(19) United States
(12) Patent Application Publication
(10) Pub. No.: US 2025/0301686 A1
(43) Pub. Date: Sep. 25, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung (TW)

(21) Appl. No.: 18/775,457

(22) Filed: Jul. 17, 2024

Related U.S. Application Data
(60) Provisional application No. 63/567,854, filed on Mar. 20, 2024.

(51) Int. Cl. H01L 29/775; H01L 29/06; H01L 29/423; H01L 29/66; H01L 29/786

(52) U.S. Cl. CPC H10D 30/43; H10D 30/014; H10D 30/6735; H10D 30/6757; H10D 62/121; H10D 64/017

(57) ABSTRACT

Embodiments of the present disclosure relate to a semiconductor device structure. The structure includes a substrate, an insulating material disposed on the substrate, a first fin structure extending upwardly from the substrate through the insulating material, a second fin structure extending upwardly from the substrate through the insulating material, wherein the first and second fin structures extend along a first direction. The structure also includes a first isolation trench structure disposed between the first and second fin structures, wherein the first isolation trench structure extends through the insulating material along a second direction perpendicular to the first direction, and the first isolation trench structure includes a first portion extending a first depth into the substrate and a second portion extending a second depth into the substrate, wherein the second depth is different than first depth.

### CROSS-REFERENCE TO RELATED APPLICATIONS

This application claims priority to U.S. Provisional Application Ser. No. 63/567,854 filed Mar. 20, 2024, which is incorporated by reference in their entirety.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, continued reduction of the gate pitch is necessary. Various schemes, such as poly on diffusion edge (PODE) and continuous poly on diffusion edge (CPODE), have been used to scale the gate pitch while preventing leakage current between transistors. However, it has been observed that parasitic fin bipolar transistor may form during the etch process, leading to formation of EPI-substrate-EPI leakage path.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-11A are cross-sectional side views of various stages of manufacturing the semiconductor device structure taken along line A-A of FIG. 6, in accordance with some embodiments.

FIGS. 7B-11B are cross-sectional side views of various stages of manufacturing the semiconductor device structure taken along line B-B of FIG. 6, in accordance with some embodiments.

FIGS. 7C-11C are cross-sectional side views of various stages of manufacturing the semiconductor device structure taken along line C-C of FIG. 6, in accordance with some embodiments.

FIG. 12 is a top view of the semiconductor device structure shown in FIGS. 11A, 11B, 11C, in accordance with some embodiments.

FIGS. 13A-21A are cross-sectional side views of various stages of manufacturing the semiconductor device structure taken along line D-D of FIG. 12, in accordance with some embodiments.

FIGS. 13B-21B are cross-sectional side views of various stages of manufacturing the semiconductor device structure taken along line E-E of FIG. 12, in accordance with some embodiments.

FIGS. 13C-21C are cross-sectional side views of various stages of manufacturing the semiconductor device structure taken along line F-F of FIG. 12, in accordance with some embodiments.

FIGS. 13D-21D are cross-sectional side views of various stages of manufacturing the semiconductor device structure taken along line G-G of FIG. 12, in accordance with some embodiments.

FIG. 22 is a top view of the semiconductor device structure shown in FIGS. 21A-21D, in accordance with some embodiments.

FIG. 23 is a top view of the semiconductor device structure shown in FIGS. 21A-21D, in accordance with an alternative embodiment.

FIG. 24 is a cross-sectional side view of a portion of an IC device having the semiconductor device structure with an exemplary arrangement of CMODE structures, in accordance with some embodiments.

FIGS. 25A-33A are cross-sectional side views of various stages of manufacturing the semiconductor device structure taken along line D-D of FIG. 12, in accordance with some embodiments.

FIGS. 25B-33B are cross-sectional side views of various stages of manufacturing the semiconductor device structure taken along line E-E of FIG. 12, in accordance with some embodiments.

FIGS. 25C-33C are cross-sectional side views of various stages of manufacturing the semiconductor device structure taken along line F-F of FIG. 12, in accordance with some embodiments.

FIG. 34 is a top view of the semiconductor device 100 shown in FIGS. 33A-33C, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure describe an improved process for blocking leakage current through epitaxial source/drain features, transistors, and silicon substrates by running a Cut-Metal Gate (CMG) process over a Continuous-Metal-On-Diffusion-Edge (CMODE) process. Embodiments of the present disclosure are applicable to any devices which may include CMG structures and CMODE (or CPODE) structures, such as planar FETs, Fin-FETs, Horizontal Gate All Around (HGAA) FETs, Vertical Gate All Around (VGAA) FETs, and other suitable devices.

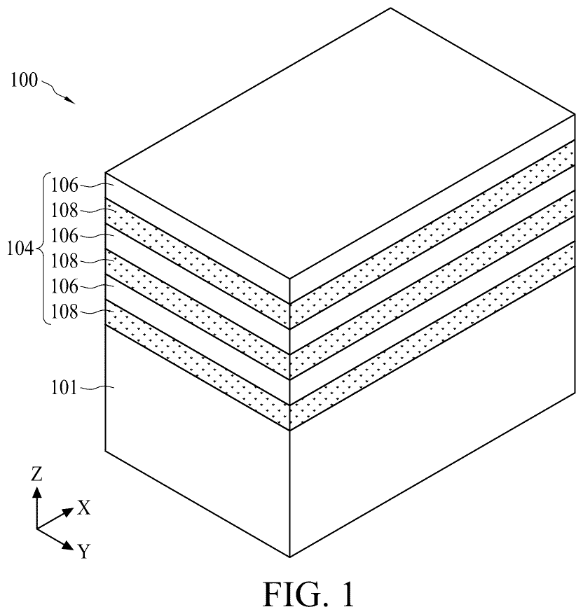

FIGS. 1 to 34 show exemplary processes for manufacturing a semiconductor device structure 100 according to embodiments of the present disclosure. It is understood that additional operations can be provided before, during, and after processes shown by FIGS. 1 to 34, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-well region and boron for a p-well region.

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof. It is contemplated that the material for the second semiconductor layers 108 can be etched and replaced by other materials, such as SiO or SiN, during the subsequent processes.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

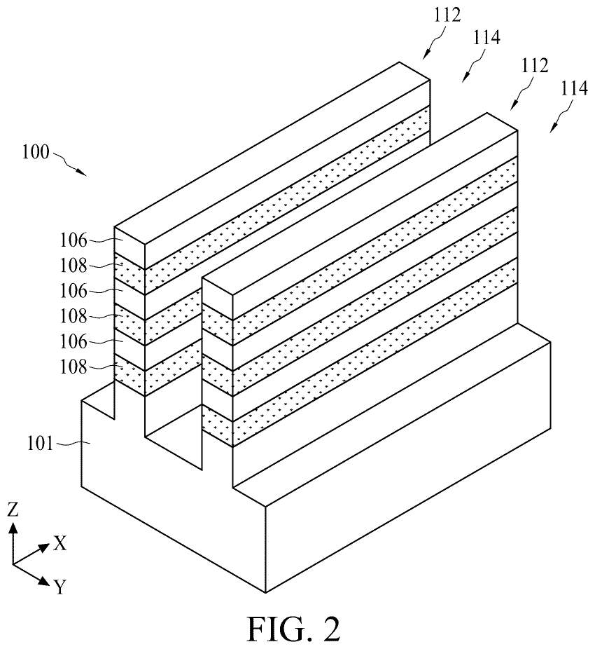

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, each fin structure 112 has a longitudinal axis along the X direction.

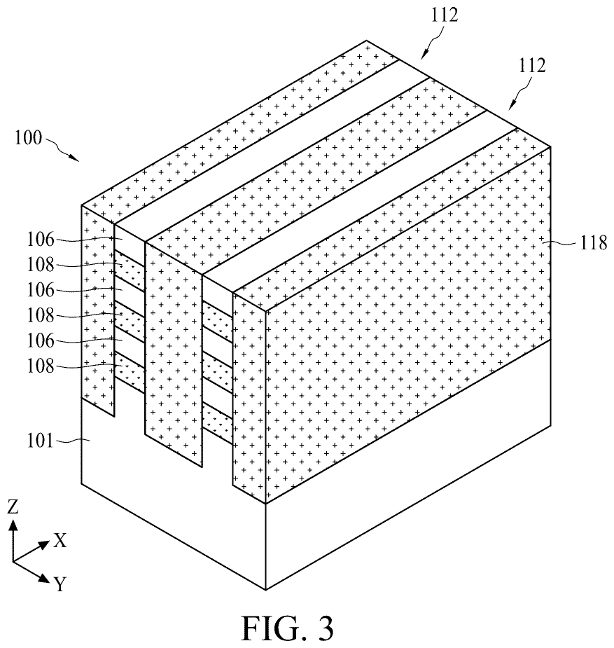

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

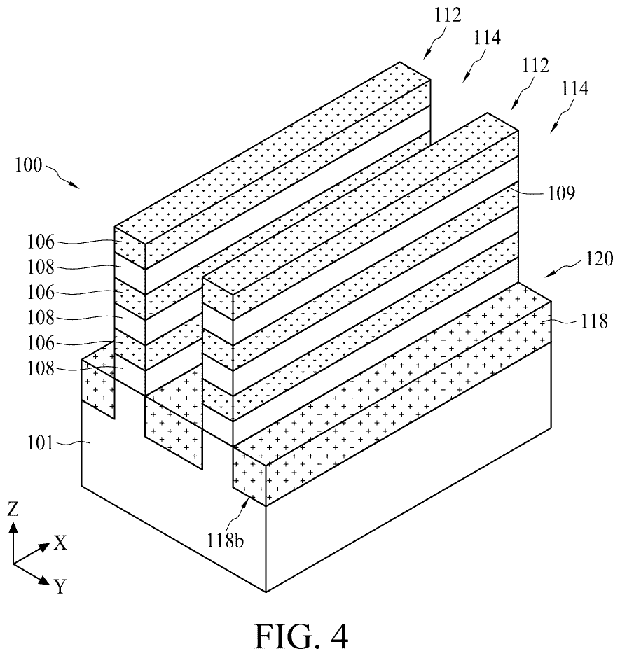

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

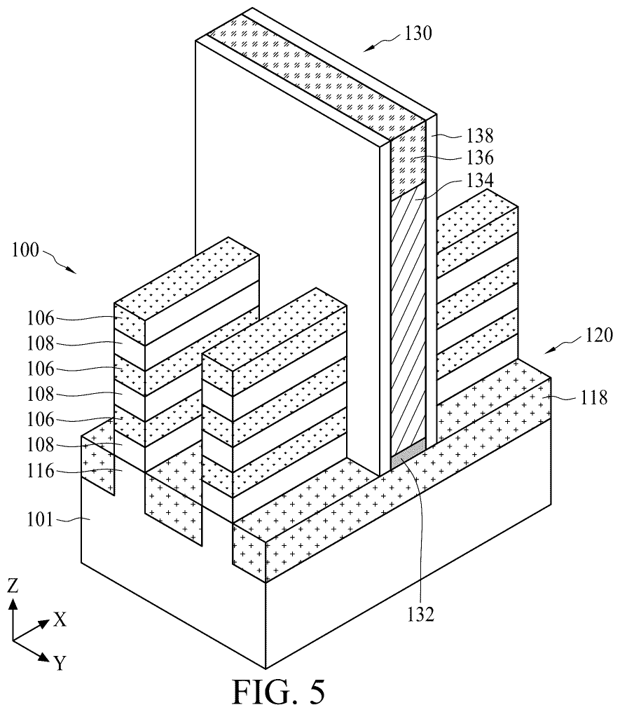

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on the sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

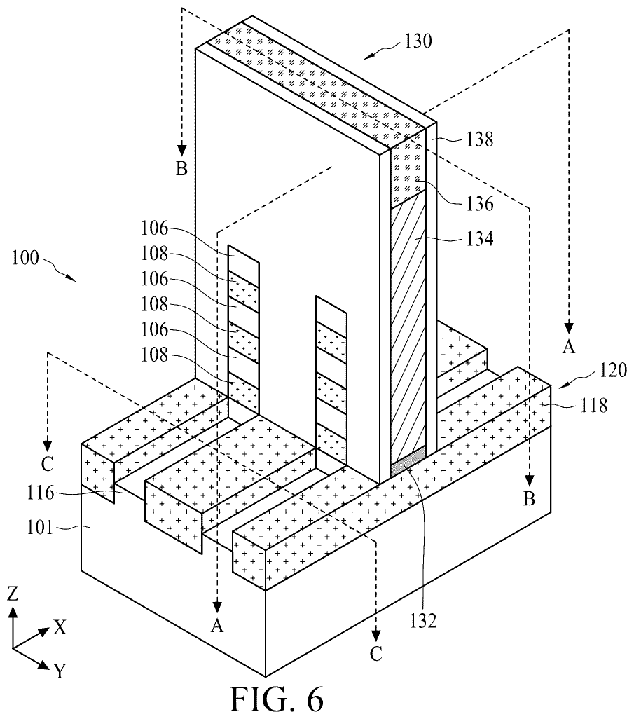

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

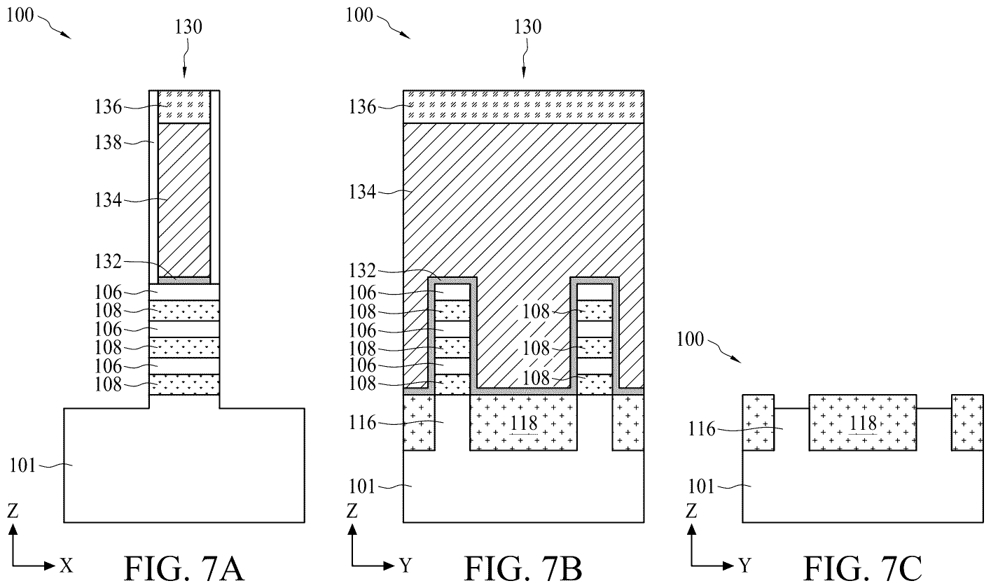

FIGS. 7A, 7B, and 7C to 11A, 11B, and 11C are cross-sectional side views of one of various stages of manufacturing the semiconductor device structure 100 taken along line A-A, line B-B, and line C-C of FIG. 6, respectively.

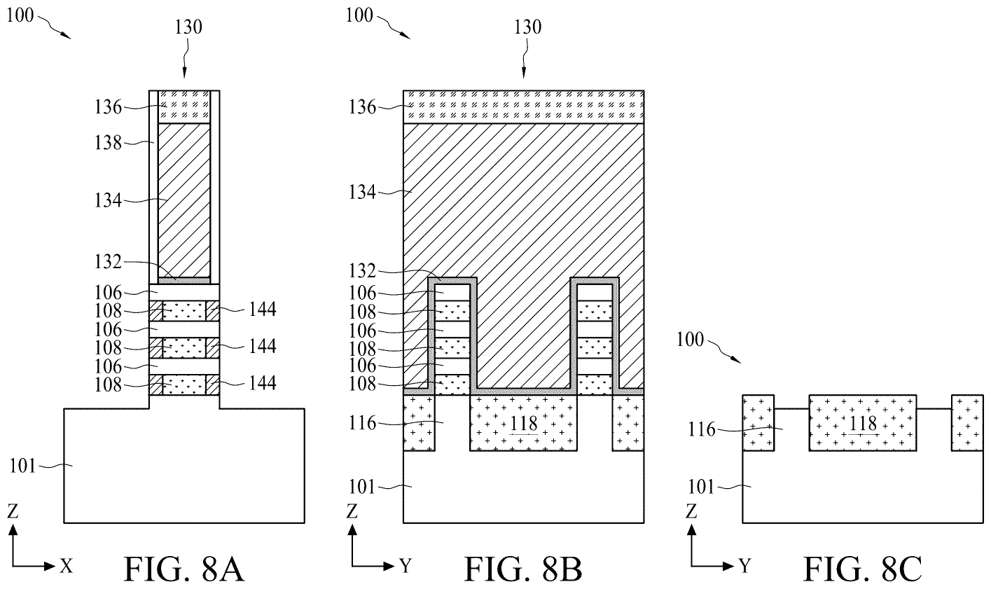

In FIGS. 8A, 8B, and 8C, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SIN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

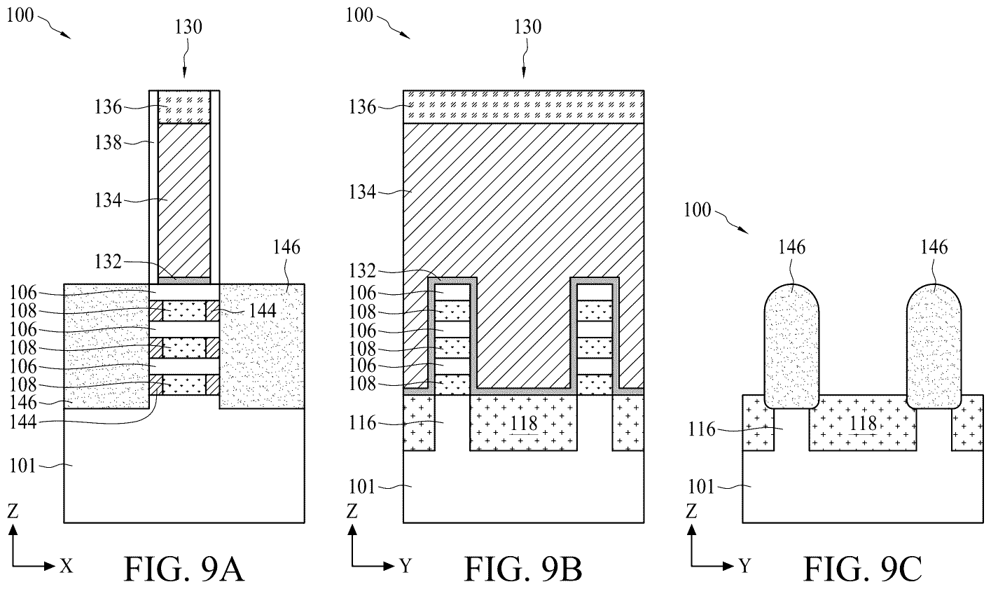

In FIGS. 9A, 9B, and 9C, source/drain (S/D) regions 146 are formed from the substrate portions 116. In some embodiments, the S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

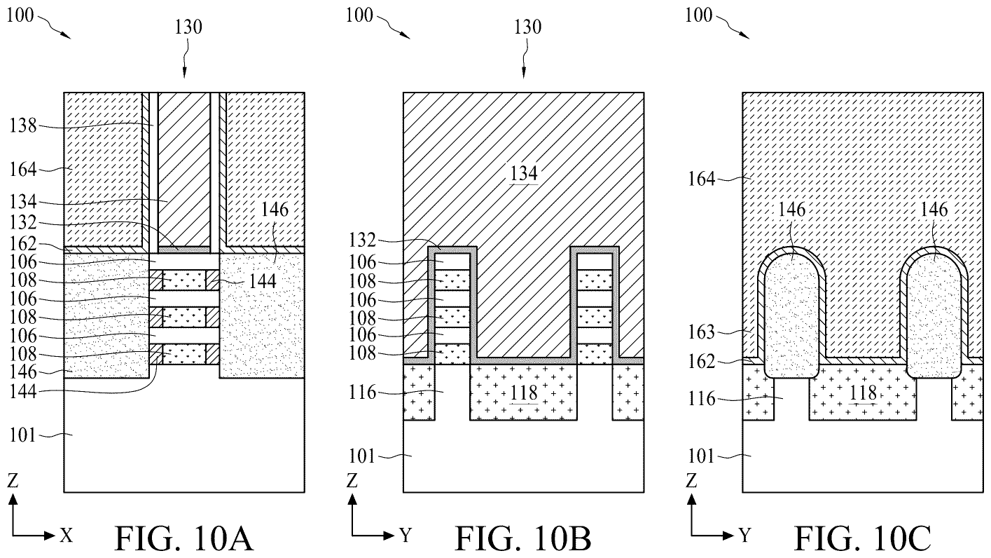

In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to cure the ILD layer 164. After the ILD layer 164 is formed, a planarization operation, such as CMP, is performed on the semiconductor device structure 100 until the sacrificial gate electrode layer 134 is exposed. After the planarization process, the top surfaces of the CESL 162, the gate spacers 138, and the sacrificial gate electrode layer 134 are substantially co-planar.

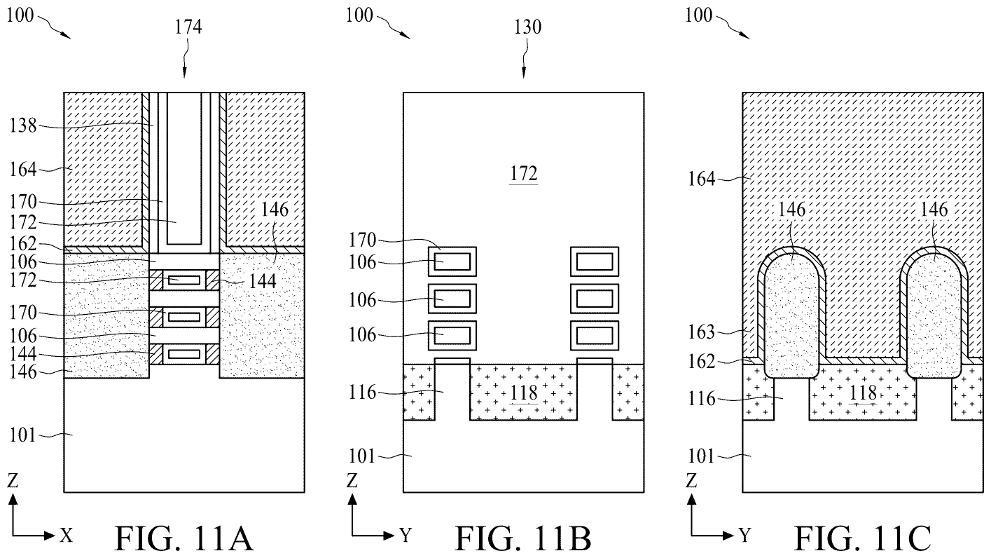

In FIGS. 11A, 11B, and 11C, the sacrificial gate structure 130 and second semiconductor layers 108 are removed. The ILD layer 164 protects the epitaxial S/D features 146 during the removal of the sacrificial gate structure 130. The sacrificial gate structure 130 can be removed using plasma dry etching and/or wet etching. The removal of the second semiconductor layers 108 exposes the dielectric spacers 144 and the first semiconductor layers 106. As a result, openings are formed around the first semiconductor layers 106, and the portion of the first semiconductor layers 106 not covered by the dielectric spacers 144 is exposed to the openings. Then, replacement gate structures 174 are formed. The replacement gate structures 174 may each include a gate dielectric layer 170 and a gate electrode layer 172. The gate dielectric layer 170 is formed on the exposed surfaces of the semiconductor device structure 100. The gate dielectric layer 170 may include or made of a high-k dielectric material. The gate dielectric layer 170 may be a conformal layer formed by a conformal process, such as an ALD process, a PECVD process, a molecular-beam deposition (MBD) process, or the like, or a combination thereof.

After formation of the gate dielectric layer 170, the gate electrode layer 172 is formed on the gate dielectric layer 170. The gate electrode layer 172 filles the openings and surrounds a portion of each of the first semiconductor layers 106. The gate electrode layer 172 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The gate electrode layers 172 may be formed by PVD, CVD, ALD, electro-plating, or other suitable method. In some embodiments, one or more optional conformal layers (not shown) can be conformally (and sequentially, if more than one) deposited between the gate dielectric layer 170 and the gate electrode layer 172. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 172, the one or more optional conformal layers (if any), and the gate dielectric layer 170 above the top surfaces of the ILD layer 164, the CESL 162, and the gate spacers 138 may be removed by a planarization process, such as by a CMP process. After the CMP process, the top surfaces of the ILD layer 164, the CESL 162, the gate spacers 138, the gate dielectric layer 170, and the gate electrode layer 172 are substantially co-planar.

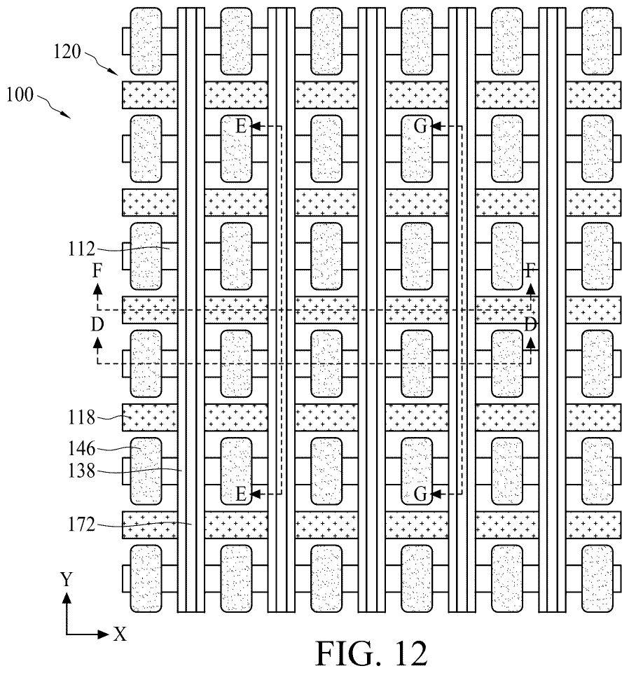

FIG. 12 is a top view of the semiconductor device structure 100 shown in FIGS. 11A, 11B, 11C, in accordance with some embodiments. Some components of the semiconductor device structure 100, such as the ILD layer 164, the gate dielectric layer 170, and the CESL 162, etc., are omitted in FIG. 12 for the sake of clarity. Furthermore, the locations of the S/D regions 146 and the isolation regions 120 (i.e., insulating material 118) are for illustration and are not exact. As shown in FIG. 12, the semiconductor device structure 100 includes S/D regions 146 formed on opposite sides of the gate electrode layer 172. Each gate electrode layer 172 has a longitudinal axis along the Y direction, while each fin structure 112 has the longitudinal axis along the X direction.

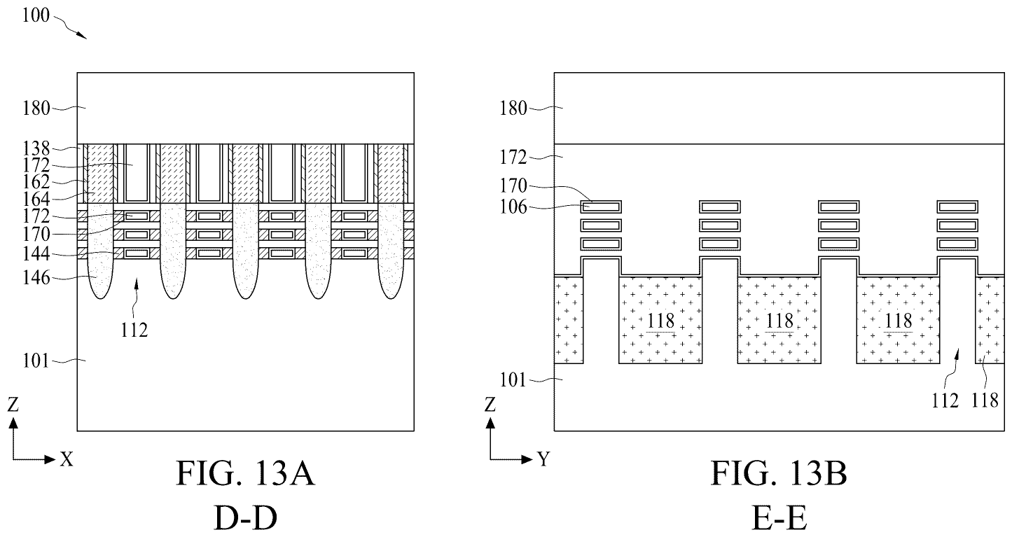

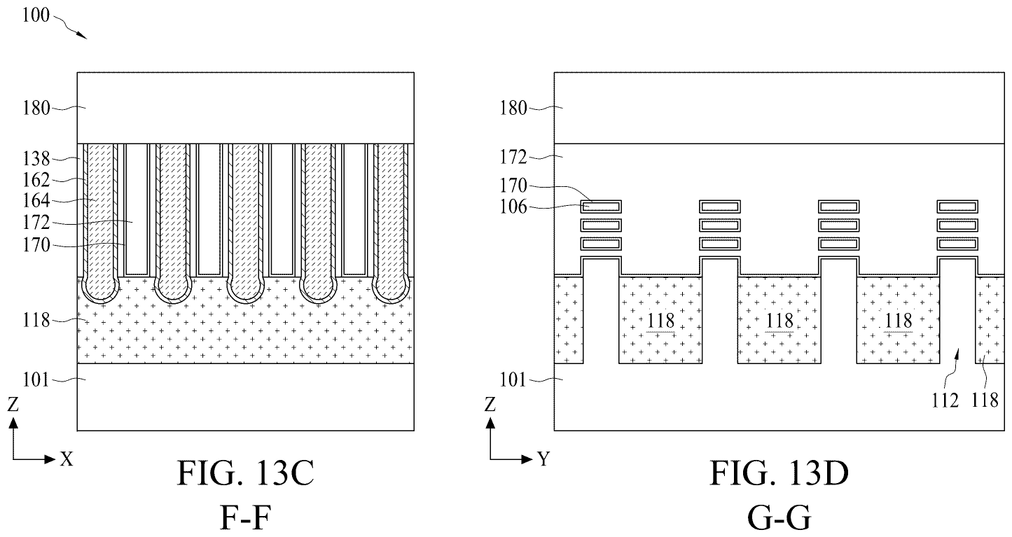

FIGS. 13A-21A are cross-sectional side views of various stages of manufacturing the semiconductor device structure 100 taken along line D-D of FIG. 12, in accordance with some embodiments. FIGS. 13B-21B are cross-sectional side views of various stages of manufacturing the semiconductor device structure 100 taken along line E-E of FIG. 12, in accordance with some embodiments. FIGS. 13C-21C are cross-sectional side views of various stages of manufacturing the semiconductor device structure 100 taken along line F-F of FIG. 12, in accordance with some embodiments. FIGS. 13D-21D are cross-sectional side views of various stages of manufacturing the semiconductor device structure 100 taken along line G-G of FIG. 12, in accordance with some embodiments. As shown in FIGS. 13A-13D, a mask layer 180 is formed on the top surfaces of the gate dielectric layer 170, the gate spacers 138, gate electrode layers 172, the CESL 162, and the ILD layer 164. The mask layer 180 may include a dielectric layer, such as SiN, or a semiconductor material, such as amorphous silicon.

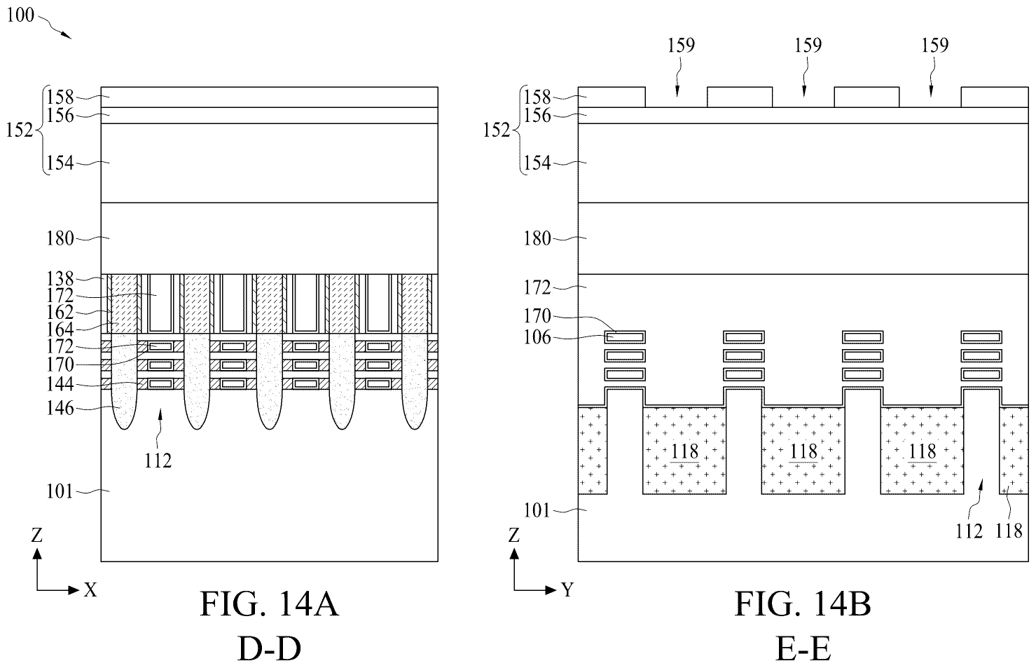

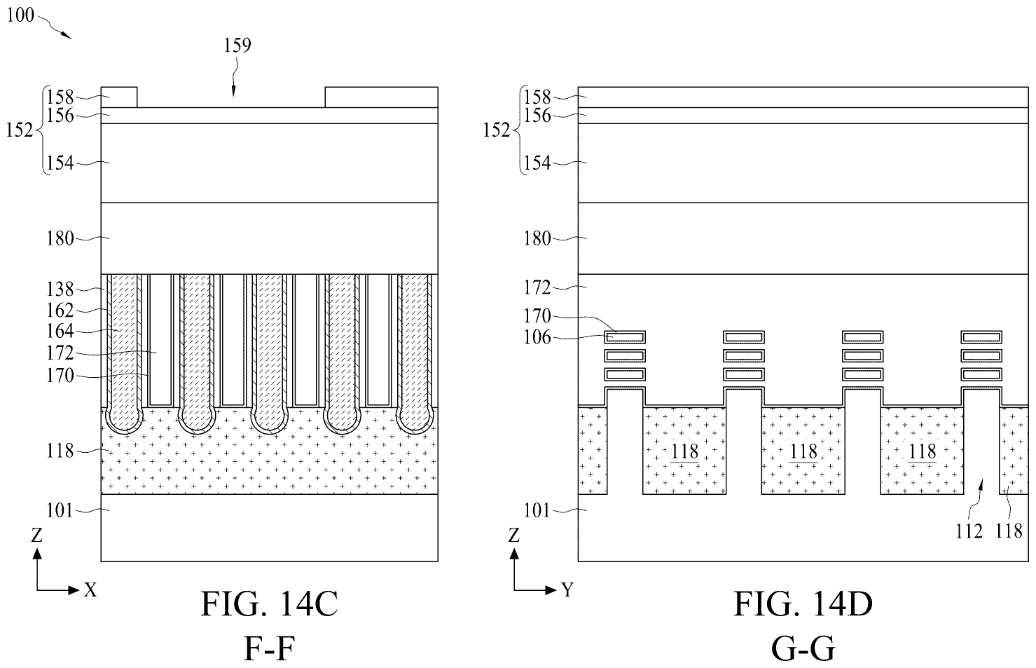

In FIGS. 14A-14D, a mask structure 152 is formed on the mask layer 180. In some embodiments, the mask structure 152 is a tri-layer photoresist. For example, the mask structure 152 may include a bottom layer 154 and a middle layer 156 disposed on the bottom layer 154. The bottom layer 154 and the middle layer 156 are made of different materials such that the optical properties and/or etching properties of the bottom layer 154 and the middle layer 156 are different from each other. In some embodiments, the bottom layer 154 may be a carbon layer, and the middle layer 156 may be a silicon-rich layer designed to provide an etch selectivity between the middle layer 156 and the bottom layer 154. The mask structure 152 further includes a photoresist layer 158 that may be a chemically amplified photoresist layer and can be a positive tone photoresist or a negative tone photoresist. The photoresist layer 158 may include a polymer, such as phenol formaldehyde resin, a poly(norbornene)-co-malaic anhydride (COMA) polymer, a poly(4-hydroxystyrene) (PHS) polymer, a phenol-formaldehyde (bakelite) polymer, a polyethylene (PE) polymer, a polypropylene (PP) polymer, a polycarbonate polymer, a polyester polymer, or an acrylate-based polymer, such as a poly (methyl methacrylate) (PMMA) polymer or poly (methacrylic acid) (PMAA). The photoresist layer 158 may be formed by spin-on coating. The photoresist layer 158 is patterned to have openings 159 formed therein. The openings 159 are arranged to align with one or more gate electrode layers 172. In some embodiments, the openings 159 may extend across at least three gate electrode layers 172 along the X-direction.

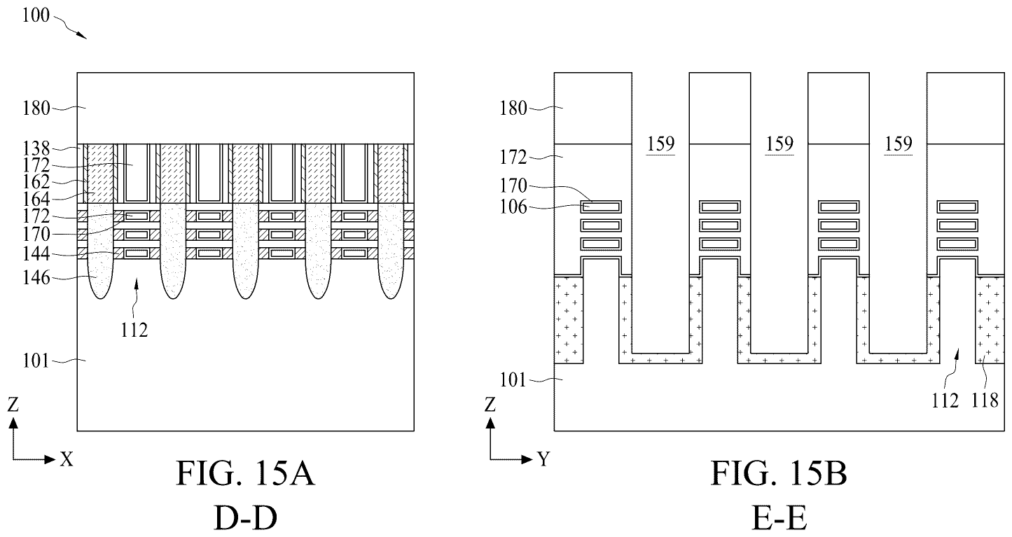

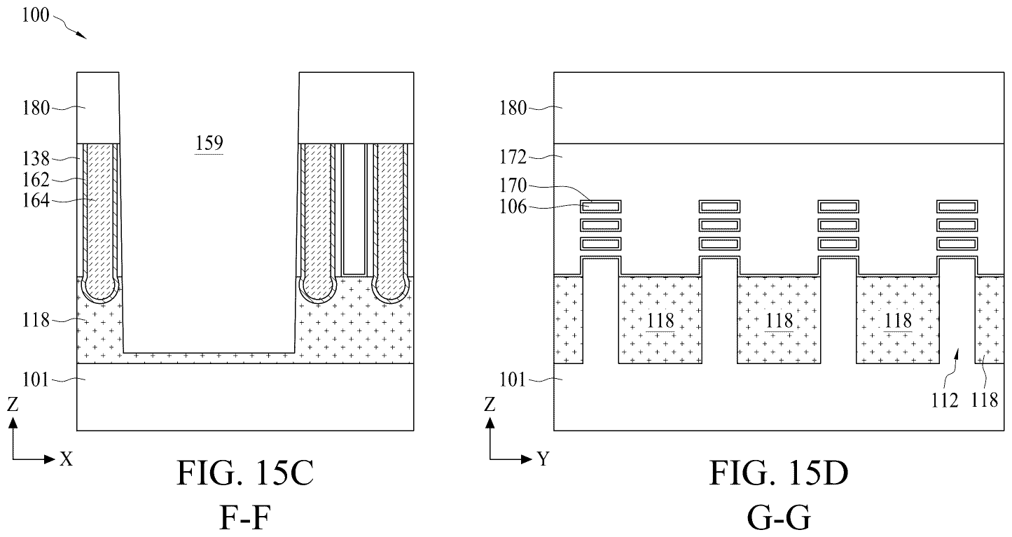

In FIGS. 15A-15D, the openings 159 are extended into the middle layer 156, the bottom layer 154, and the mask layer 180. The mask structure 152 may be removed after the openings 159 are extended into the mask layer 180. Portions of the gate electrode layers 172 and gate dielectric layers 170 are exposed in the openings 159. Next, the openings 159 are extended through the gate electrode layers 172, the gate dielectric layer 170, and into the insulating material 118 by removing the exposed portions of the gate electrode layers 172, the gate dielectric layer 170, and the insulating material 118, as shown in FIG. 15B and 15C. The openings 159 may be formed by one or more etch processes. The openings 159 extend a thickness into the insulating material 118 so that a thin layer of the insulating material 118 remains on the exposed surface of the substrate 101. As shown in FIG. 15C, in some embodiments, the gate spacers 138 are protected by the mask layer 180 and are not removed during the removal of the portions of the gate electrode layers 172 and gate dielectric layer 170.

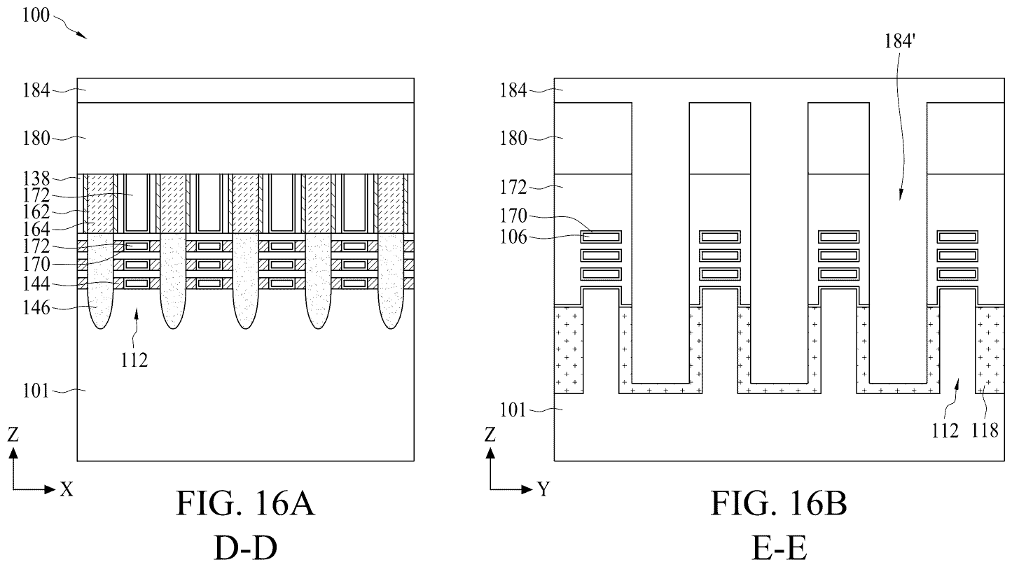

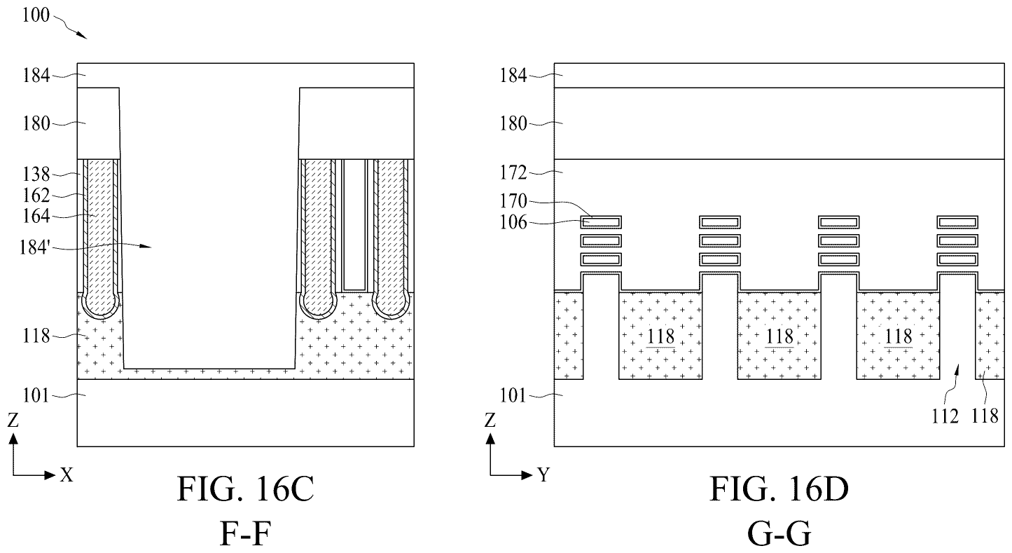

In FIGS. 16A-16D, a dielectric material 184 is deposited in the openings 159. The dielectric material 184 within the openings 159 forms cut metal gate (CMG) structures 184′. The CMG structures 184′ divide a gate electrode layer 172 into two or more portions, and the two or more portions may be controlled independently. The dielectric material 184 may be a low etch resistivity material. In some embodiments, the dielectric material 184 is a nitrogen-containing material, such as silicon nitride, silicon oxynitride (SiON), SiOCN, SiCN; an oxygen-containing material, such as silicon oxide (SiO₂); a low-K dielectric material; or any suitable dielectric material. In one exemplary embodiment, the dielectric material 184 is a nitride. The dielectric material 184 may be formed by any suitable process, such as a CVD, PECVD, FCVD, or ALD process.

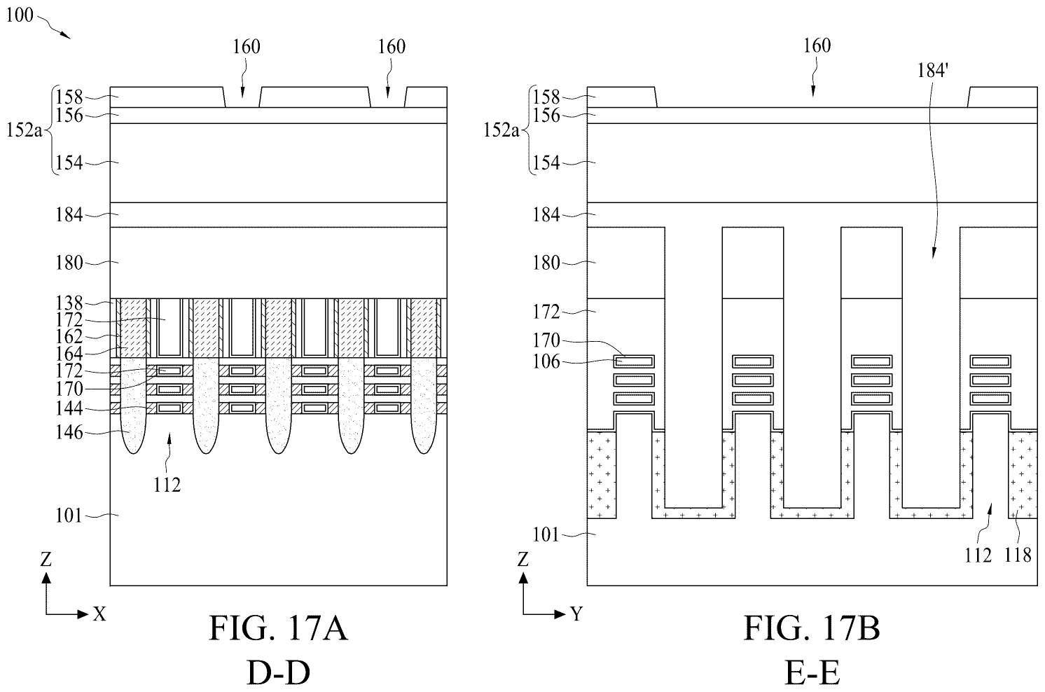

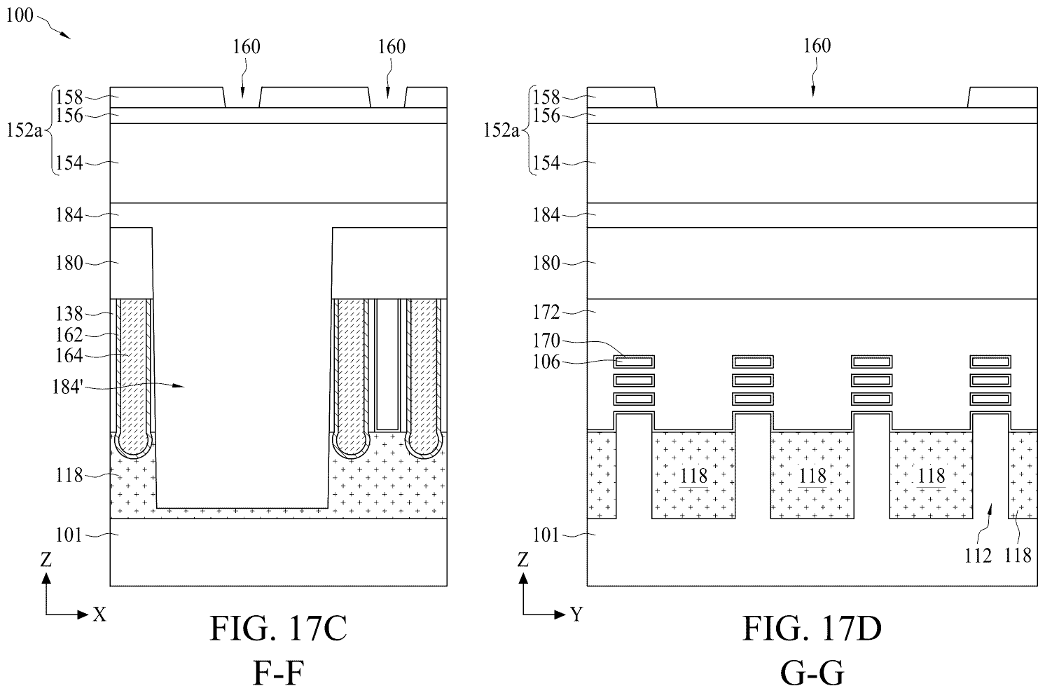

In FIG. 17A-17D, a mask structure 152a, such as the mask structure 150, is formed on the dielectric material 184. Likewise, the mask structure 152a is a tri-layer photoresist including a bottom layer 154, a middle layer 156 disposed on the bottom layer 154, and a photoresist layer 158. The photoresist layer 158 is patterned to have openings 160 formed therein. The patterned photoresist layer 158 is used as a mask during a subsequent process, such as one or more photolithographic processes, to transfer the pattern (i.e., openings 160) in the photoresist layer 158 into the middle layer 156, the bottom layer 154, the dielectric material 184, and the mask layer 180.

In various embodiments, the openings 160 are arranged to cross over a portion of the CMG structures 184′. The openings 160 define an isolation region to be formed in the substrate portions of the fin structures 112. The isolation region may be disposed between neighboring active regions. The term “active region” refers to a region where transistors are formed. As will be discussed in more detail below, the isolation regions may be formed by performing a fin-cut (or sheet-cut) process and filling the fin-cut (or sheet-cut) regions with a dielectric. This fin-cut (or sheet-cut) process may be referred to continuous metal on diffusion edge (CMODE) process. The term “diffusion edge” is equivalently referred to as an active edge, which is an edge abutting adjacent active regions. The CMODE process can be used to reduce gate pitch, thereby increasing the density for multi-gate devices and thus device performance required for aggressively scaled circuits and devices. In any case, the pattern (i.e., openings 160) in the photoresist layer 158 are arranged at locations where portions of the CMG structures 184′ and the replacement gate structures 174 are to be revealed in a later stage.

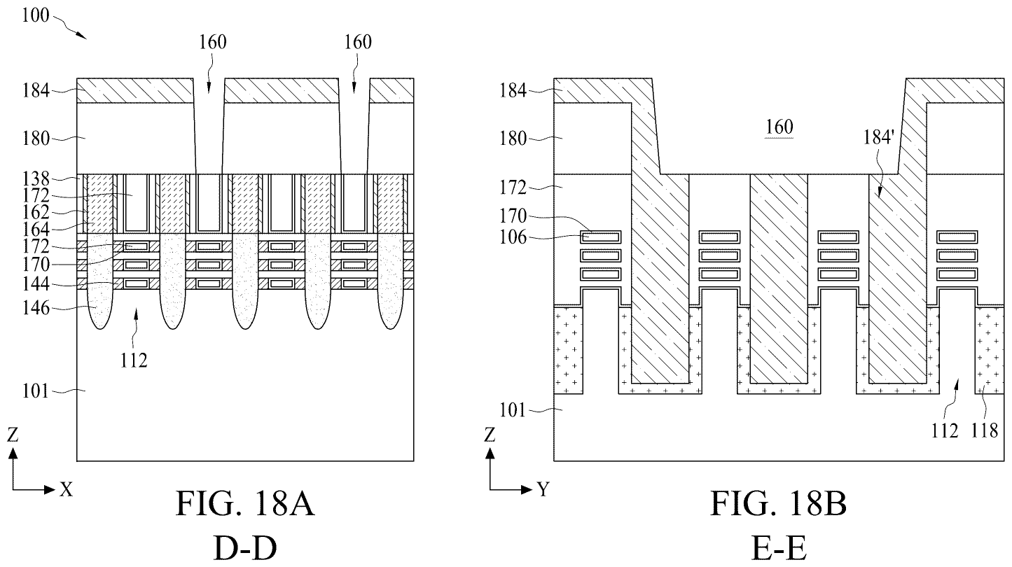

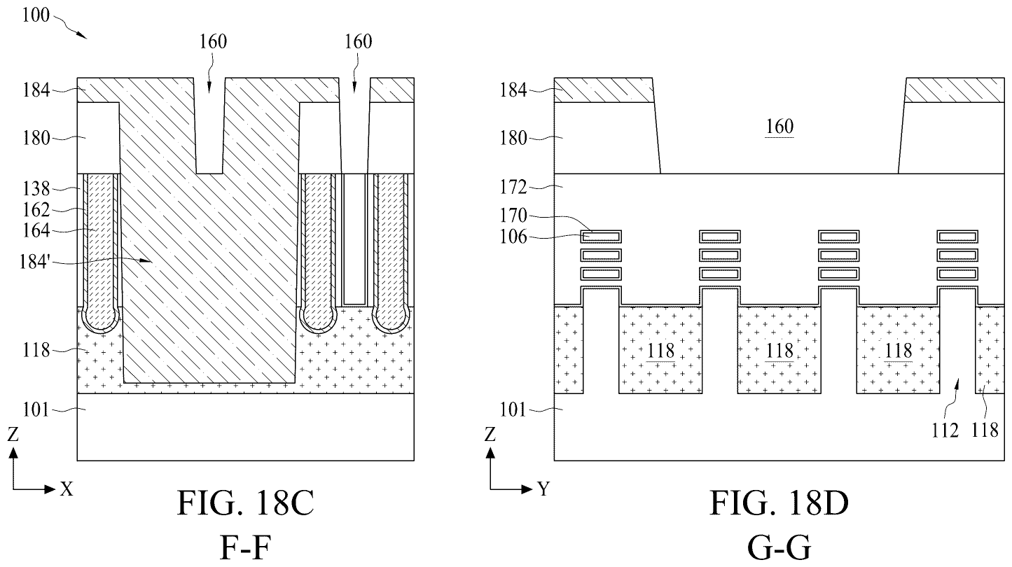

In FIGS. 18A-18D, the patterns (i.e., openings 160) in the photoresist layer 158 are transferred to the mask layer 180 to form patterned mask layer, and the bottom layer 154, the middle layer 156, the photoresist layer 158 are removed. The formation of the patterned mask layer 180 may be achieved by one or more photolithographic processes. As a result of the one or more photolithographic processes, openings 160 are formed in the CMG structures 184′ and the patterned mask layer 158, and a portion of the gate electrode layer 172 is exposed. In some embodiments, the opening 160 exposes a portion of a gate electrode layer 172, and the exposed portion of the gate electrode layer 134 extends across multiple fin structures 112. In some embodiments, the exposed portion of the gate electrode layer 172 extends over two fin structures 112, as shown in FIGS. 18B and 18D below.

The one or more photolithographic processes may stop as soon as the gate electrode layer 172 is exposed. As can be seen, the openings 160 expose portions of the CMG structures 184′ and a plurality of gate electrode layers 172 along the Y direction. The patterned mask layer 180 may then be used to protect active regions during subsequent fin-cut (or sheet-cut) process.

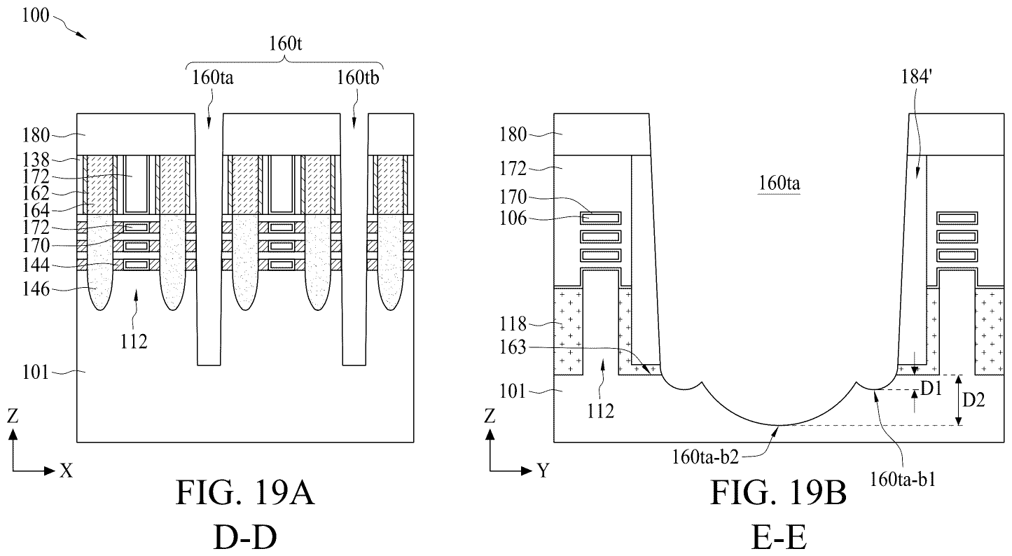

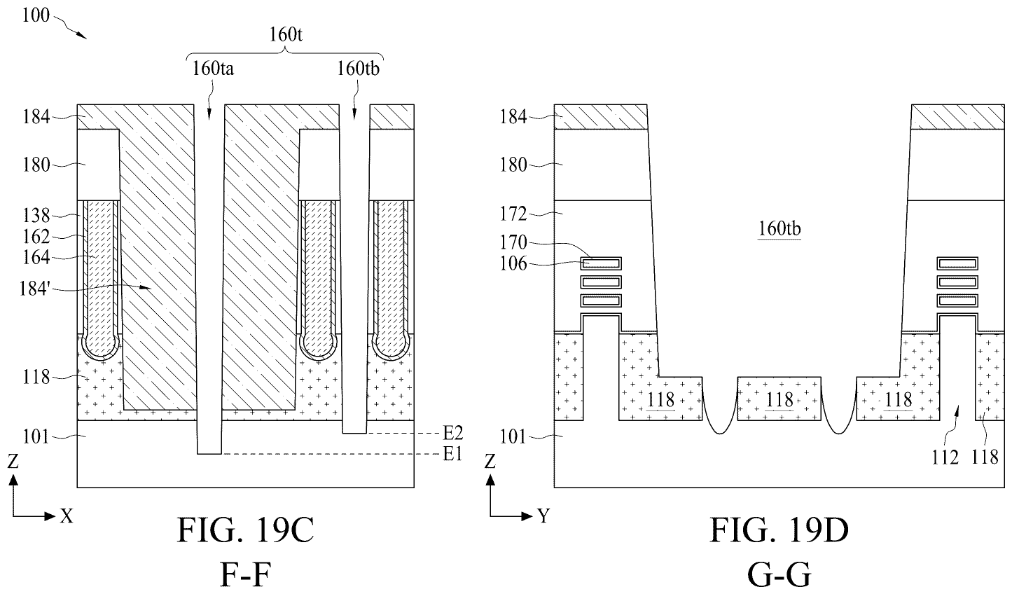

In FIG. 19A-19D, the exposed portions of the gate electrode layer 172, the insulating material 118, the CMG structures 184′, and the fin structures 112 (including the first semiconductor layers 106 and the gate dielectric layer 170 surrounding each of the first semiconductor layers 106) are removed by one or more etch processes. The exposed portion of the gate electrode layer 172 is removed, using the patterned mask layer 180 as a mask, by a suitable metal etch process. The metal etch process removes the gate electrode layer 172 but does not substantially affect the gate spacers 138, the ILD layer 164, and the CESL 162 during the etch process. The metal etch process may also remove a portion of the CMG structures 184′ and the fin structures 112. The metal etch process may be a dry etch, a wet etch, or a combination thereof. In some embodiments, the metal etch process is a chlorine-based dry etch process. Exemplary chlorine-based etch chemistry may include, but are not limited to, Cl₂, CHCl₃, CCl₄, BCl₃, or the like, or a combination thereof. In one example, the metal etch process uses an etchant comprising Cl₂ and BCl₃.

The fin structures 112, the insulating material 118, and the dielectric material 184 (i.e., CMG structures 184′) may be removed by a fin-cut process. The fin-cut process is performed using the patterned mask layer 180 as an etching mask. The fin-cut process may be dry etch, reactive ion etch (RIE), and/or other suitable processes. The fin-cut process is performed so that the exposed first semiconductor layers 106, the gate dielectric layer 170, and portions of the substrate 101 forming the fin structures 112 are selectively removed. A portion of the insulating material 118 around the fin structures 112 is also removed. The fin-cut process may be a self-aligned CMODE etch process (RCP). Depending on the materials to be etched, the self-aligned CMODE etch process can be configured to be a high selective etch of silicon over silicon oxide, or a low selective etch of silicon over silicon oxide. A high selective etch may be achieved by a two-step etch scheme comprising an anisotropic etching process and an isotropic etching process. The anisotropic etching process may be a plasma etch using a bromine-based (e.g., HBr) or a chlorine-based (e.g., Cl₂) etch chemistry. The isotropic etching process may be a plasma etch using a fluorine-based (e.g., NF₃) and/or a hydrogen-based (e.g., H₂) etch chemistry. In some embodiments, O₂ and/or CO₂ may be used in conjunction with the HBr/Cl₂ based chemistry to enhance directional etch of silicon. Higher directionality can be achieved by adding a bias power to a substrate pedestal in the process chamber. In some embodiments, a bias power is applied during both the anisotropic etching process and the isotropic etching process. In some embodiments, a bias power is applied during the anisotropic etching process and the isotropic etching process is performed without a bias power. Alternatively, the anisotropic etching process may be a dry etch process and the isotropic etching process may be a wet etch process to achieve high selective etch between the substrate 101 and the insulating material 118.

A low selective etch may be achieved by a chlorine-based (e.g., Cl₂ and/or BCl₃) etch chemistry. Higher BCl₃ supply may lead to more consumption of silicon oxide, thereby reducing the etch selectivity between silicon and silicon oxide.

In some embodiments, after the metal etch process and prior to the fin-cut process, the semiconductor device structure 100 may be exposed to a gas mixture to form an oxide-based or carbon-based passivation layer on the exposed surfaces of the patterned mask layer 180, the gate electrode layer 172, the insulating material 118, and the CMG structures 184′. The passivation layer helps preserve the critical dimension (CD) of the openings 160 so that the openings 160 are extended into the substrate portions with a proper CD. The oxide-based passivation layer may be formed by exposing the semiconductor device structure 100 to a chlorine-containing gas (e.g., SiCl₄), a bromine-containing gas (e.g., HBr), an oxygen-containing gas (e.g., O₂), or any combination thereof. The carbon-based passivation layer may be formed by exposing the semiconductor device structure 100 to a C—H based chemistry (e.g., CH₄), an inert gas (e.g., Ar and/or N2). Exemplary chlorine-based etch chemistry may include, but are not limited to, SiCl₄, BCl₃, Cl₂, CHCl₃, and/or CCl₄, or the like, or a combination thereof. Suitable C-H based chemistries may include, but are not limited to CF₄, CH₄, CHF₃, CH₂F₂, CHF₃, C₄F₆, or the like. In such cases, an etch process using etch chemistries comprising fluorine-containing gas (e.g., CF₄) and an inert gas (e.g., Ar) may be performed to break through the oxide-based or carbon-based passivation layer. Exemplary fluorine-based etch chemistry or fluorine-containing gas may include, but are not limited to, CF₄, SF₆, CH₂F₂, C₂H₄F₂, CHF₃, C₂F₆, or the like, or a combination thereof. A cyclic process including repetitions of a passivation step and a break-through step may be performed until a predetermined depth of the isolation trenches 160t is reached.

An exemplary self-aligned CMODE etch process may utilize an ICP/resonant antenna plasma source driven by an RF power generator using an AC electrical current operating on a tunable frequency of multiple of 13.56 MHz or 27 MHz. The process chamber may be operated at a pressure in a range of about 1 mTorr to about 100 mTorr and a temperature of about 10 degrees Celsius to about 200 degrees Celsius. The RF power generator is operated to provide source power between about 0 W to about 2500 W. A bias power operating in a range of about 0 W to about 2000 W is applied to the pedestal. The source power is used to form a plasma from HBr, O₂, and Ar (plasma etching step) and CF₄ and Ar (if break-through step was used). In some cases, a pulse plasma etch may be used. In such cases, the output of the power generator may be controlled by a pulse signal having a duty cycle in a range of about 5% to 95%. One or more etch conditions may be controlled to achieve low selectivity etch between silicon (e.g., substrate 101) and silicon oxide (e.g., insulating material 118). For example, a HBr-based etch process with low-pressure (e.g., chamber pressure below about 50 mTorr) and/or high bias power to the substrate pedestal (e.g., greater than 300 V) may be utilized during the self-aligned CMODE etch process to compensate for etch selectivity needed for removing the insulating material 118 and the substrate portion of the fin structures 112.

As a result of the fin-cut process, isolation trenches 160ta, 160tb (collectively referred to as isolation trenches 160t) are formed and extended into portions of the substrate 101 forming the fin structures 112. The isolation trenches 160t are to be filled with a dielectric material and form CMODE structures. In any case, the isolation trenches 160t (and thus subsequent CMODE structures) are formed with a depth sufficient to block leakage current, which may otherwise flow through epitaxial source/drain features, transistors, and silicon substrates. In some embodiments, the bottom of the isolation trenches 160t may be at an elevation into an accumulation region of the substrate 101. The term “accumulation region” refers to a non-conductive region in the substrate 101, which is below a depletion region (a conductive region located at/near the well portion of the substrate 101).

The isolation trenches 160t may have different depths, which may vary depending on the location of the substrate 101. In various embodiments, the isolation trenches 160ta at and/or cross the CMG structures 184′ (e.g., FIGS. 19B and 19C) may have a first depth, and the isolation trenches 160tb that do not come across the CMG structures 184′ (e.g., FIGS. 19A and 19D) may have a second depth that is shorter than the first depth. The depth difference of the isolation trenches 160t is due partly to the fact that majority of the oxides (e.g., insulating material 118) have been previously removed during formation of the CMG structures. The chemistry used for forming the CMODE thus can remove the nitrides (e.g., CMG structures 184′) at a faster rate than silicon (e.g., fin structures 112), resulting in the isolation trenches 160t with different depths. For example, the isolation trenches 160ta extending through the CMG structures 184′, the insulating material 118, and the substrate 101 may have a bottom at a first elevation E1 in the substrate 101, and the isolation trenches 160tb extending through the gate electrode layer 182, the first semiconductor layers 106, the gate dielectric layer 170, the insulating material 118, and the substrate 101 may have a bottom at a second elevation E2 that is higher than the first elevation E1 (FIG. 19C).

Such a difference in depth is also reflected in regions where the isolation trenches come across the CMG structures 184′ and the gate electrode layer 172 (FIG. 19B). As can be seen in FIG. 19B, the isolation trenches 160t may have a first portion extending through the CMG structures 184′, the insulating material 118, and into the substrate 101, and a second portion extending through the gate electrode layer 182, the first semiconductor layers 106, the gate dielectric layer 170, the insulating material 118, and into the substrate 101. The first portion of the isolation trenches 160t may extend a first depth D1 into the substrate 101, wherein the first depth D1 is measured from an interface 163 defined by the insulating material 118 and a top surface 101ts of the substrate 101 to a bottom 160ta-b1 of the first portion of the isolation trenches 160t. The second portion of the isolation trenches 160t may extend a second depth D2 into the substrate 101, wherein the second depth D2 is measured from the interface 163 to a bottom 160ta-b2 of the first portion of the isolation trenches 160t. In one embodiment, the second depth D2 is greater than the first depth D1. The vertical distance between the bottom 160ta-b1 of the first portion and the bottom 160ta-b2 of the first portion of the isolation trenches 160t may be in a range of about 10 nm to about 20 nm, such as about 15 nm. In some embodiments, each bottom 160ta-b1 and 160ta-b2 may have a curved profile. The combination of the bottoms 160ta-b1 and 160ta-b2 thus result in the isolation trenches 160t with a wavy or waved-like bottom profile, in which the bottom at the center region of the isolation trenches 160t is at a lower elevation than the bottom of the isolation trenches 160t at the peripheral region.

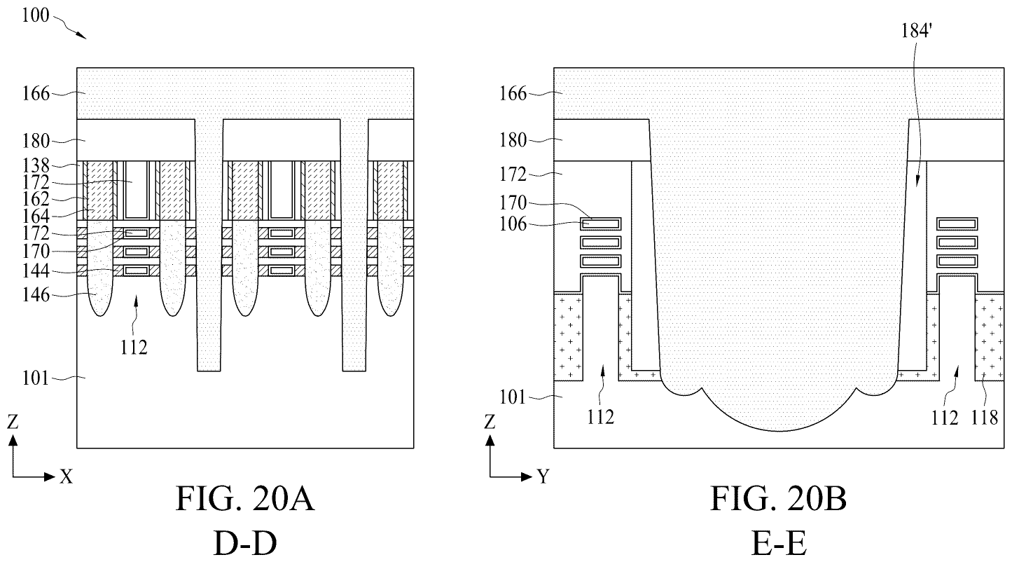

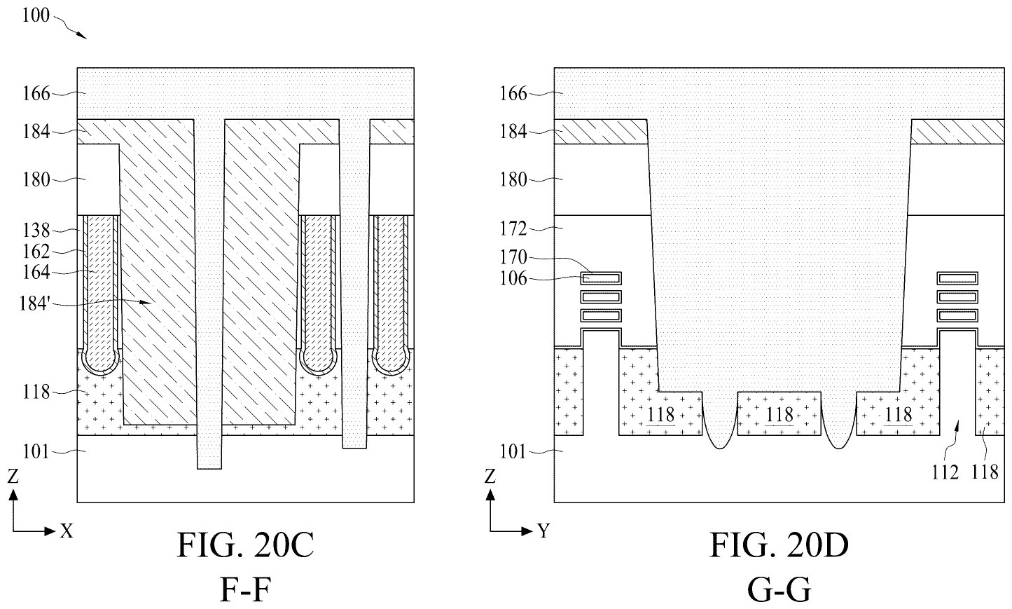

In FIGS. 20A-20D, a refill dielectric material 166 is formed in the isolation trenches 160t. In some embodiments, a dielectric liner (not shown) may be disposed between the dielectric material 166 and the exposed surfaces of the isolation trenches 160t. The dielectric material 166 and the dielectric liner filled within the isolation trenches 160t form isolation trench structures 167ta, 167tb (collectively referred to as CMODE structures 167. The dielectric material 166 and the dielectric liner may be made of an oxygen-containing material, such as silicon oxide (SiO₂); a nitrogen-containing material, such as silicon nitride, silicon oxynitride (SiON), SiOCN, SiCN; a low-K dielectric material; or any suitable dielectric material. The dielectric material 166 may include a material chemically different than the and the dielectric liner, and may be formed by any suitable process, such as a CVD, PECVD, FCVD, or ALD process. The dielectric liner may be deposited by a conformal process, such as ALD.

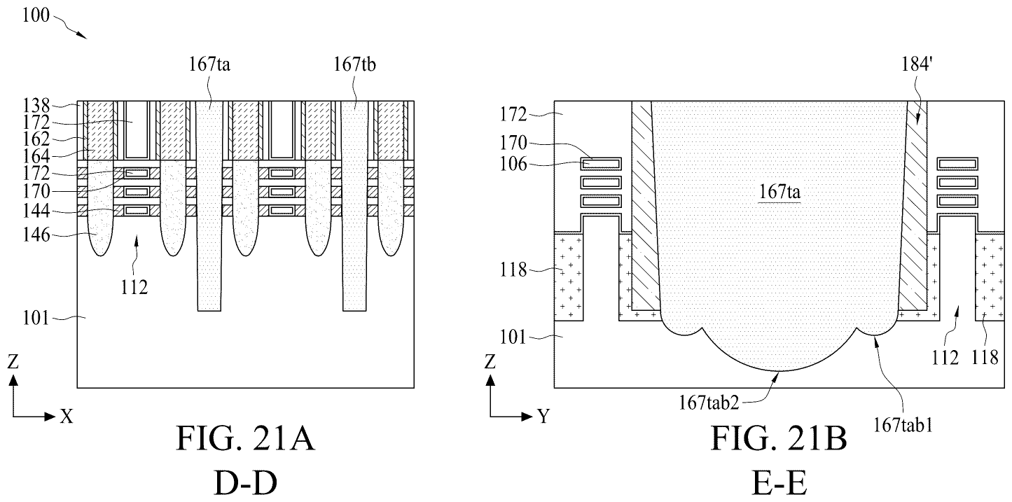

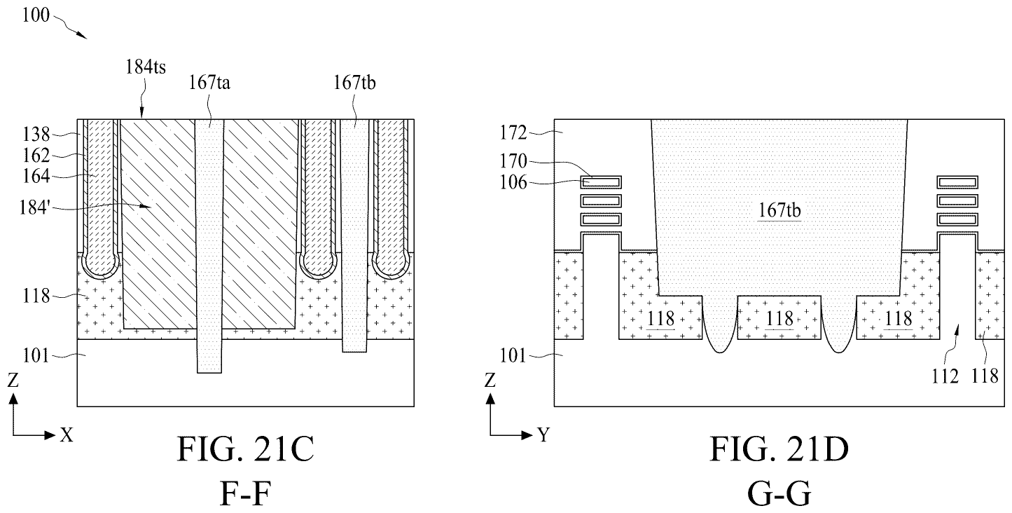

In FIGS. 21A-21D, once the isolation trenches 160t are filled, a planarization process, such as a CMP process, may be performed to remove portions of the dielectric material formed over the patterned mask layer 180. The planarization process may continue until a portion of the ILD layer 164 is exposed. As can be seen in FIG. 21C, 21D and 22, the isolation trench structure 167ta (i.e., CMODE structure 167) overlaps with a portion of the CMG structure 184′, and the isolation trench structures 167ta extends through the entire body of the CMG structure 184′ from a top surface 184ts to a bottom surface 184bs. The isolation trench structures 167ta further extends through the insulating material 118 and into the substrate 101. The isolation trench structure 167tb, which does not overlap with the CMG structure 184′, extends through the gate electrode layer 172, the insulating material 118, and into the substrate 101. Particularly, the CMODE structure 167 (e.g., isolation trench structures 167ta) extending across the CMG structure 184′ have a deeper depth than the CMODE structure 167 (e.g., isolation trench structures 167tb) that is entirely free from contact with the CMG structure 184′. In some embodiments, the isolation trench structures 167ta along the X-direction has a first dimension and CMG structure 184′ along the X-direction has a second dimension greater than the first dimension. The top surfaces of the isolation trench structures 167ta, 167tb and the CMG structure 184′ are substantially co-planar.

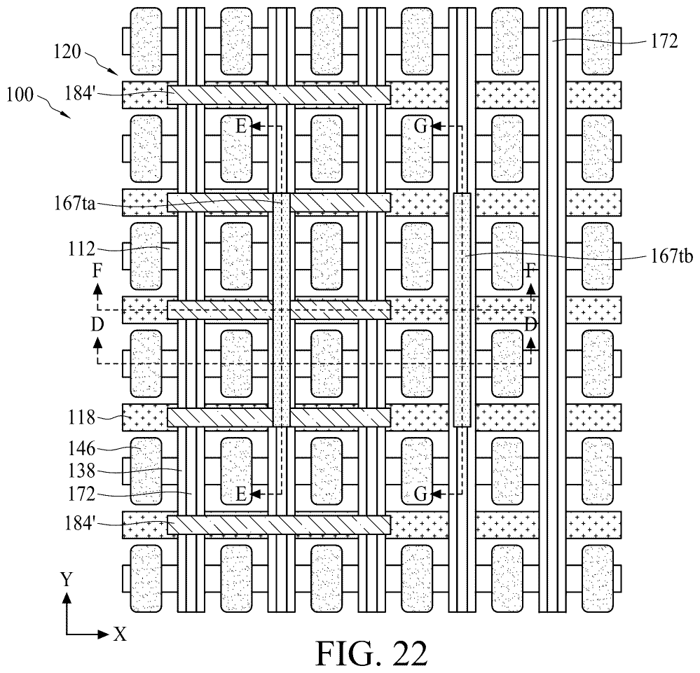

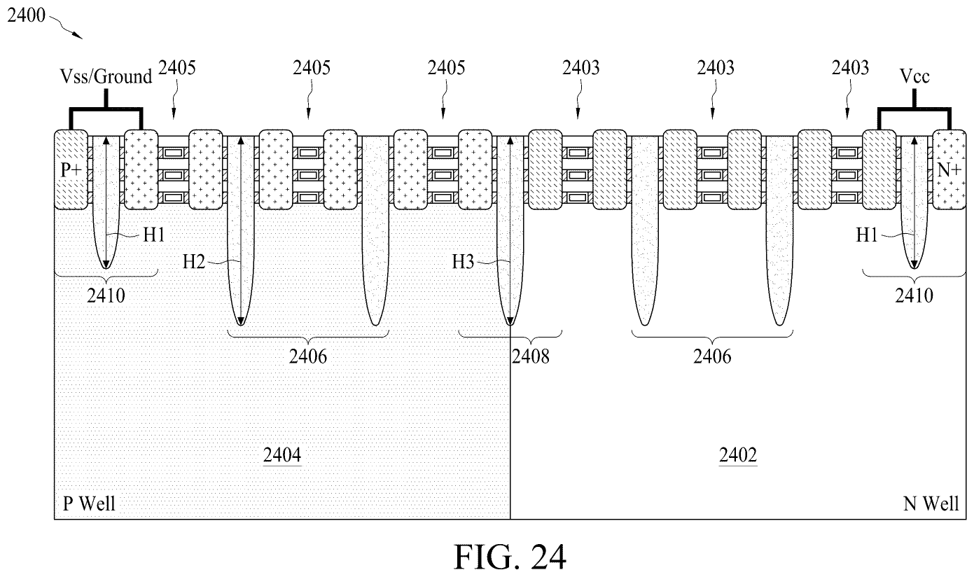

FIG. 22 is a top view of the semiconductor device structure 100 shown in FIGS. 21A-21D, in accordance with some embodiments. Some components of the semiconductor device structure 100, such as the ILD layer 164, the CESL 162, are omitted in FIG. 22 for clarity. In some embodiments, the CMODE structures 167ta may be intra-well isolations 2406 (FIG. 24) and inter-well isolations 2408 (FIG. 24) disposed within the well regions or at well boundaries of an IC device, and the CMODE structures 167tb may be pick-up isolations 2410 (FIG. 24) disposed at pick-up wells, such as wells at Vcc and Vss in an IC device.

FIGS. 17A to 21D described a process of cutting protruding fin structures 112 and may be referred to as a Continuous Metal On-Diffusion Edge (CMODE) process, or sometimes referred to as a Cut Metal on-Diffusion Edge (CMODE) process, which is to divide active region into multiple segments or to isolate active devices. It is appreciated that in the illustrated embodiments, a CMODE process is performed after a CMG process, in which the cutting of protruding fin structures is performed after the formation of replacement gate stacks 174. In accordance with alternative embodiments, the CMODE process is performed before the CMG process. While various embodiments of the present disclosure are based on the CMODE process, the inventive concept is applicable to a Continuous Poly On-Diffusion Edge (CPODE) process or a Cut Poly On Diffusion Edge (CPODE) process, which forms an isolation trench structure during front-end-of-line (FEOL) processing.

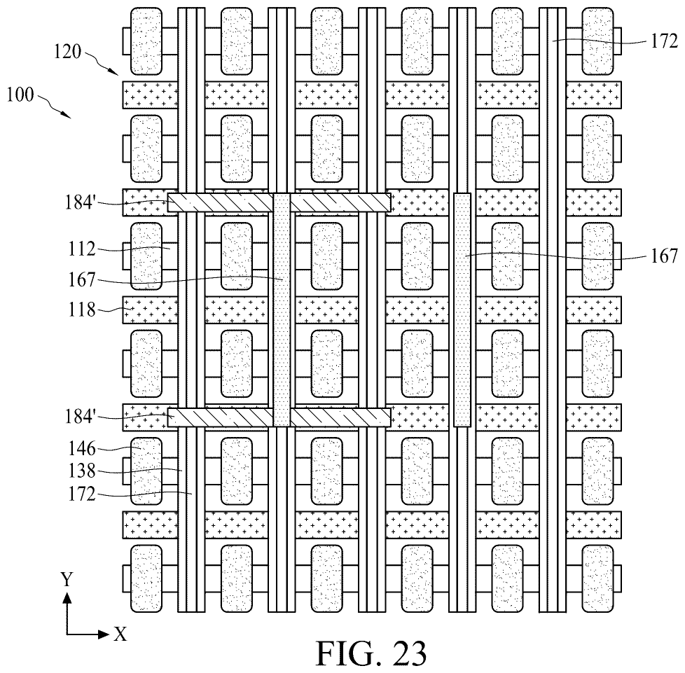

FIG. 23 is a top view of the semiconductor device structure 100 shown in FIGS. 21A-21D, in accordance with an alternative embodiment. The embodiment in FIG. 23 is substantially identical to the embodiment of FIG. 22 except that the CMG structures and the isolation regions 120 (i.e., insulating material 118) are alternatingly arranged along the Y-direction.

FIG. 24 is a cross-sectional side view of a portion of an IC device 2400 having the semiconductor device structure 100 with an exemplary arrangement of CMODE structures, in accordance with some embodiments. In circuit design, a standard cell is a block of transistors that is repeated according to a set of design rules across a design layout. A standard cell may be used for different functions. For example, a standard cell may be a static random access memory (SRAM) standard cell or a logic cell for logic operations. A standard cell may include one or more P-type transistors and one or more N-type transistors. To fabricate transistors on bulk substrates, N-type wells doped with N-type dopants and P-type wells doped with P-type dopants are formed in the bulk substrate and active regions of opposite conductivity types are formed over the respective N-type wells and P-type wells.

In the embodiment of FIG. 24, the IC device 2400 generally includes a P-type transistor 2403 having a P-type active region formed over an N-type well (N-Well) 2402 and an N-type transistor 2405 having an N-type active region formed over a P-type well (P-Well) 2404. The N-type transistor 2405 is placed adjacent to the P-type transistor 2403. The N-Well region 2402 is coupled to a positive power supply, such as Vcc, and the P-Well region 2404 is electrically coupled to electrical ground or negative (source) supply, such as Vss. The use of Vcc and Vss ensures the same electric potential (voltage) within the N-type well 2402 and the P-type well 2404. Isolation features are typically used at various locations of the IC device to avoid formation of the current leakage. For example, intra-well isolations 2406 may be disposed within the wells to help avoid leakage current through transistors and wells; inter-well isolations 2408 may be disposed at the well boundaries of high doping wells to help avoid leakage current through transistors and wells; and pick-up isolations 2410 may be disposed at pick-up wells such as wells at Vcc and Vss to help avoid leakage current through transistors. These isolation features are often made deep into the well regions to be effective in preventing current leakage. However, it has been observed that when the pick-up isolations are too deep in the well regions, well contact resistance (Rcc or Rss) may increase and trigger a parasitic PNP bipolar junction transistor (BJT) among a P-type active region, the N-type well 2402 underlying the P-type active region, and the adjacent P-type well 2404 (e.g., from Vcc to ground), and/or a parasitic NPN bipolar junction transistor along an N-type active region, the P-type well 2404 underlying the N-type active region, and the adjacent N-type well 2402 (e.g., from ground to Vcc). The parasitic NPN and PNP bipolar junction transistors may be latched-up and cause the IC device 2400 to leak current, leading to degradation of the device.

In addition, lattice mismatch and different thermal expansion properties between the substrate 101 and the dielectric material 166 (of the isolation trench structure 167) can lead to charge trapping in the interface of silicon and refill dielectric heterostructures, which occur mostly in NMOS or PMOS. Negative charges trapped in the interface of silicon and refill dielectric heterostructures may lead to P-type EPI to P-type EPI leakage through parasitic PNP BJT, while positive charges trapped in the interface of silicon and refill dielectric heterostructures may lead to N-type EPI to N-type EPI leakage through parasitic NPN BJT (i.e., intra-well leakage). When small current is provided to the well, the parasitic BJT will be turned on, resulting in substantial leakage current. While it is possible to reduce the depth of CMODE structures to prevent formation of parasitic fin-like BJT below the STI (i.e., insulating material 118), insufficient etch amount can still lead to residues of silicon on the sidewall of the STI, resulting in current leakage.

To address leakage issues above, various embodiments of the present disclosure propose a new way to etch fin structures below STI (i.e., insulating material 118) by forming pick-up isolations 2410 with a height (or depth) that is shorter than the height (or depth) of intra-well isolations 2406 and inter-well isolations 2408. The intra-well isolations 2406, the inter-well isolations 2408, and the pick-up isolations 2410 may be any CMODE/CPODE structures, such as CMODE structures 167 shown in FIGS. 21A-21D. The CMODE structures (e.g., intra-well isolations 2406 and the inter-well isolations 2408) with a greater height may be obtained by running a CMODE process at or cross over regions where CMG process was previously performed, and the CMODE structures (e.g., pick-up isolations 2410) with a shorter height may be obtained simultaneously as the intra-well isolations 2406 and the inter-well isolations 2408 by running the CMODE process at regions without the presence of CMG structures. By making the pick-up isolations 2410 shallower at pick-up wells (such as wells at Vcc and Vss) than those within the well regions or at the well boundaries, the well contact resistance (Rcc or Rss) can be reduced. As a result, the formation of parasitic BJT is avoided. With this approach, a single photomask can be used to achieve CMODE structures with different heights simultaneously at predetermined locations.

In some embodiments, the pick-up isolations 2410 at pick-up wells (such as wells at Vcc or Vss) have a first height H1, the intra-well isolations 2406 have a second height H2 that is greater than the first height H1, and the inter-well isolations 2408 have a third height H3 that is greater than the first height H1. The second height H2 and the third height H3 may be the same or different. The intra-well isolations 2406, the inter-well isolations 2408, and the pick-up isolations 2410 may be formed using the process described above with respect to FIGS. 13A-13D to 21A-21D. For example, the intra-well isolations 2406 and the inter-well isolations 2408 may be configured to be the CMODE structures 167ta in FIGS. 21A, 21B, 21C, and 22, and the pick-up isolations 2410 may be configured to be the CMODE structures 167tb in FIG. 21A, 21C, 21D, and 22.

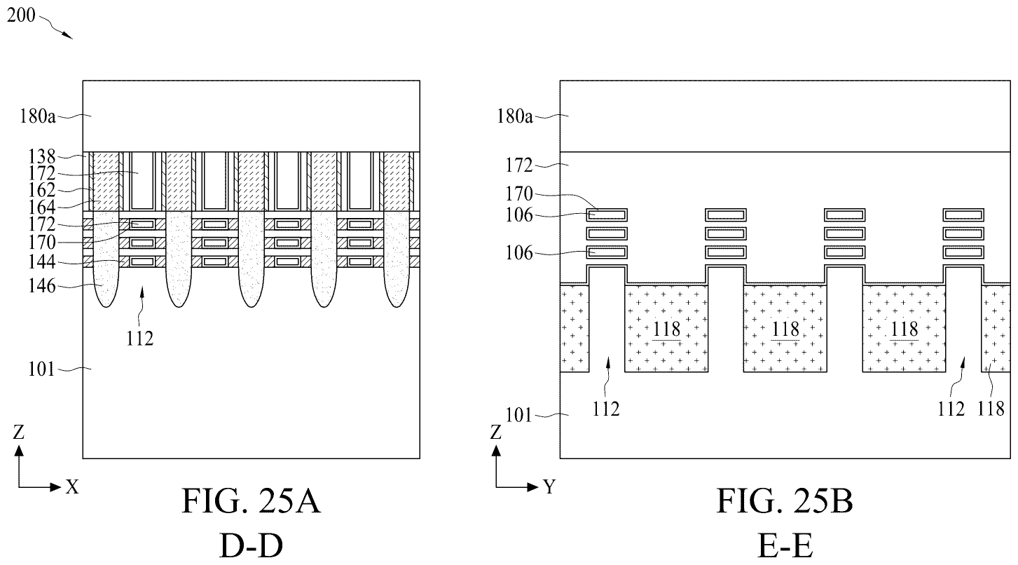

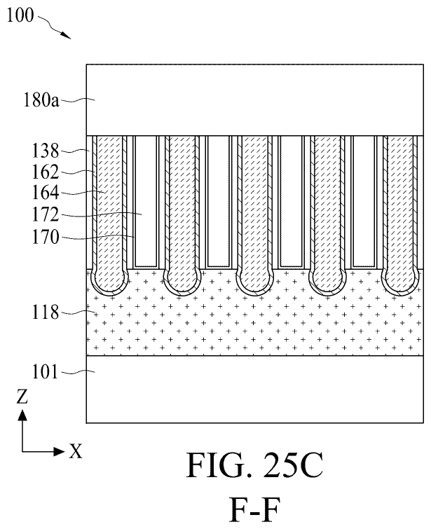

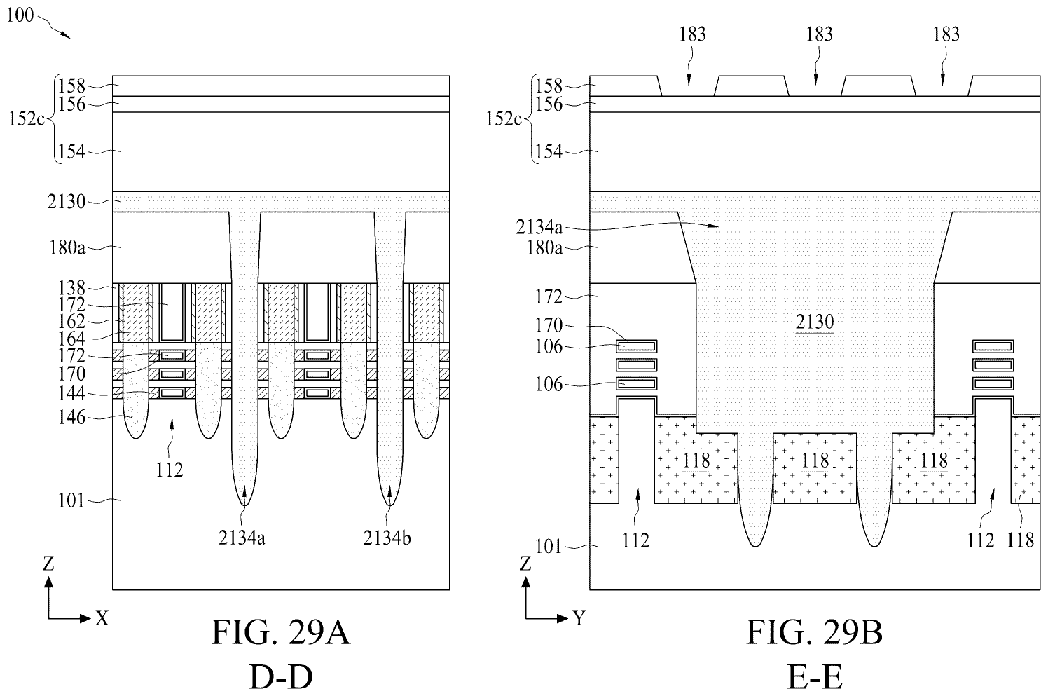

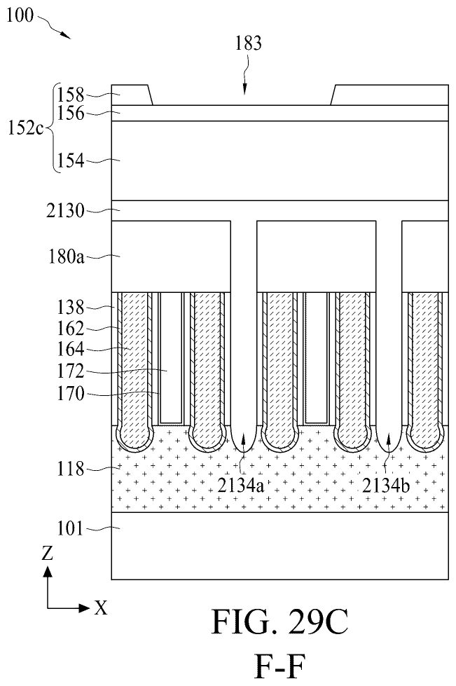

FIGS. 25A-33A are cross-sectional side views of various stages of manufacturing the semiconductor device structure 100 taken along line D-D of FIG. 12, in accordance with some embodiments. FIGS. 25B-33B are cross-sectional side views of various stages of manufacturing the semiconductor device structure 100 taken along line E-E of FIG. 12, in accordance with some embodiments. FIGS. 25C-33C are cross-sectional side views of various stages of manufacturing the semiconductor device structure 100 taken along line F-F of FIG. 12, in accordance with some embodiments. The processes described in FIGS. 25A-25C to 28A-28C may be referred to as a CMODE process, and the processes described in FIGS. 29A-29C to 33A-33C may be referred to as CMG process. While FIGS. 25A-25C to 33A-33C illustrate an embodiment combining a CMODE and a CMG process that is similar to that of FIGS. 13A-13D to 21A-21D, various processes in FIGS. 25A-25C to 33A-33C show a CMODE-first process flow, which opposes to FIGS. 13A-13D to FIGS. 21A-21D where a CMG-first process flow is illustrated.

As will be discussed in more detail below, the main differences of a CMODE process performing before a CMG process and after a CMG process are that (1) a highly anisotropic process is used to avoid the damage of neighboring metal gate is used; (2) the first part of etch process to remove metal and semiconductor heterostructure is usually a Cl₂ based process (with BCl₃ and/or HBr addition); and (3) the second part of the etch process to remove residual silicon fin structure may be HBr or Cl₂ based processes. On the other hand, a HBr-based process is usually used in the FEOL CPODE without metal existence.

In FIGS. 25A-25C, a mask layer 180a is formed on the gate electrode layers 172, the ILD layer 164, the gate spacers 138, and the CESL 162. The mask layer 180a may include the same material as the mask layer 180 discussed above.

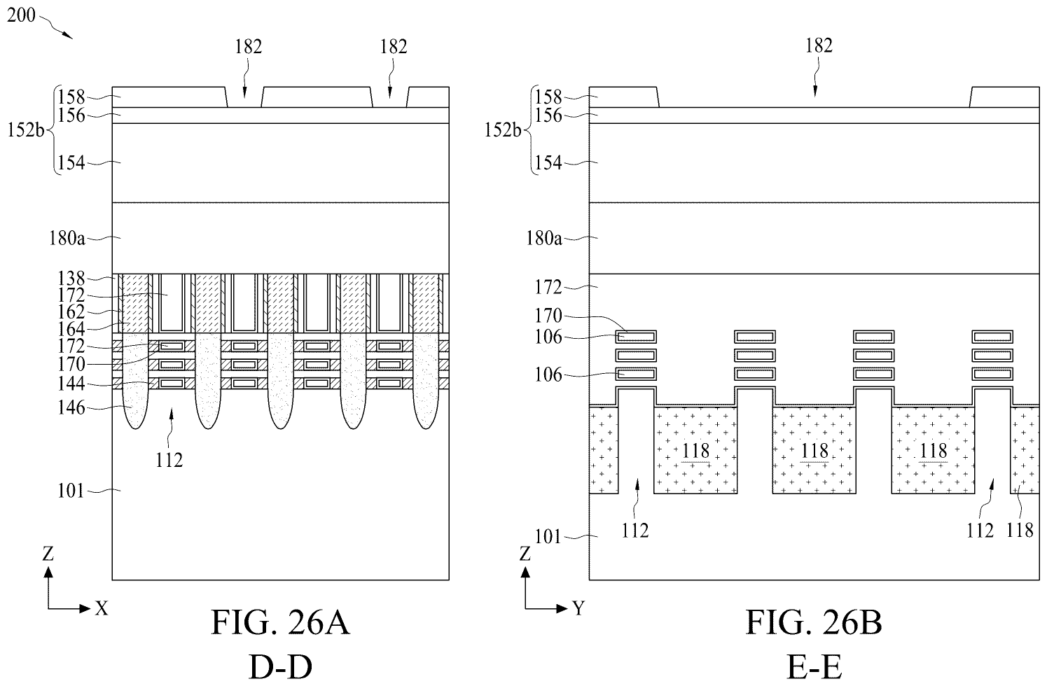

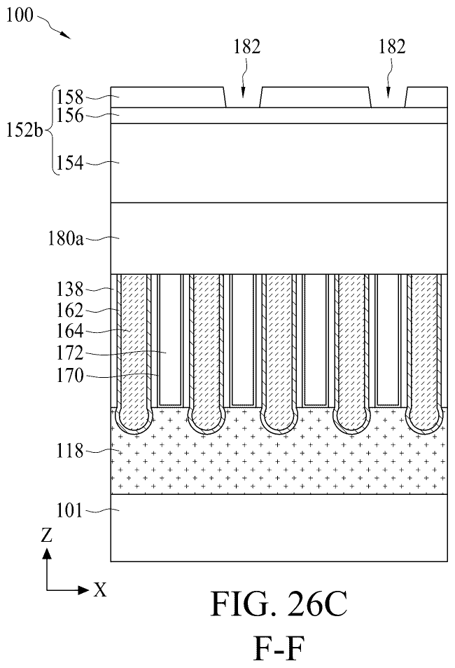

In FIGS. 26A-26C, a mask structure 152b is formed on the mask layer 180a. In some embodiments, the mask structure 152b is a tri-layer photoresist, such as the mask structure 152. For example, the mask structure 152b may include a bottom layer 154 and a middle layer 156 disposed on the bottom layer 154. Likewise, the mask structure 152b is a tri-layer photoresist including a bottom layer 154, a middle layer 156 disposed on the bottom layer 154, and a photoresist layer 158. The photoresist layer 158 is patterned to have openings 182 formed therein. The patterned photoresist layer 158 is used as a mask during a subsequent process, such as one or more photolithographic processes, to transfer the pattern (i.e., openings 182) in the photoresist layer 158 into the middle layer 156, the bottom layer 154, the CMG structures 184′, and the mask layer 180a.

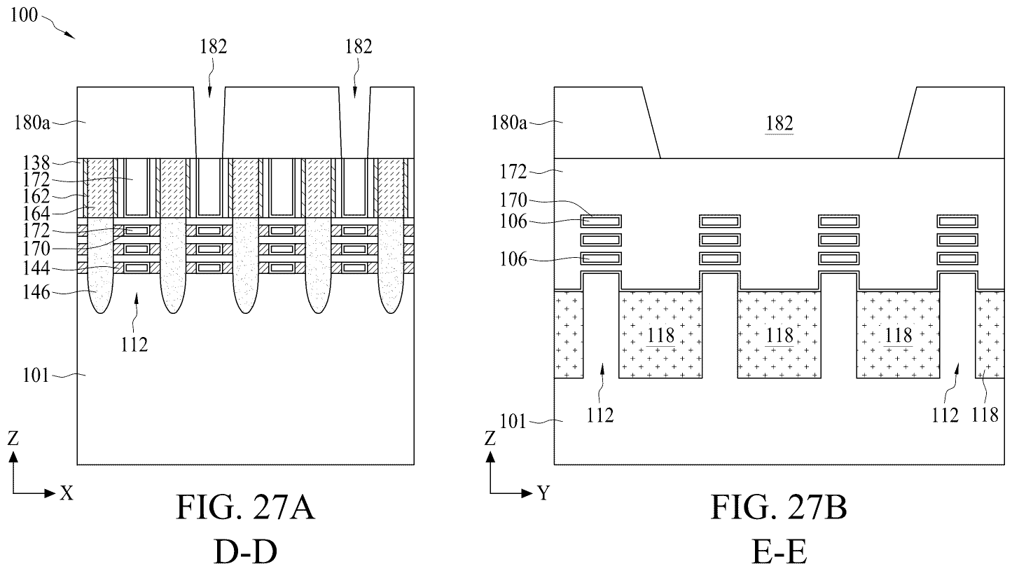

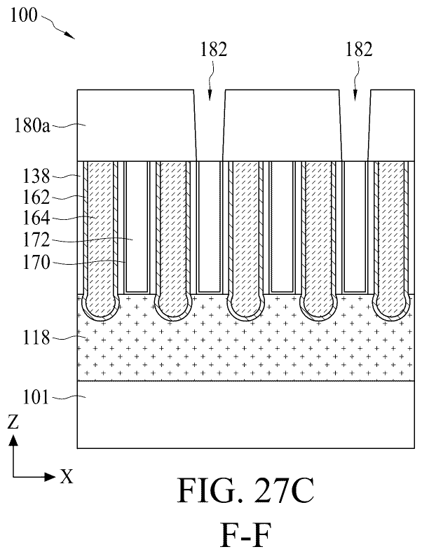

In FIGS. 27A-27C, the openings 182 are extended into the middle layer 156, the bottom layer 154, and the mask layer 180a. The mask structure 152b is removed after the openings 182 are extended into the mask layer 180a. Portions of the gate electrode layers 172 and gate dielectric layers 170 are exposed in the openings 182. Next, the openings 182 are extended through the gate electrode layers 172 and the gate dielectric layer 170 by removing the exposed portions of the gate electrode layers 172 and the portions of the gate dielectric layer 170. In some embodiments, the openings 182 are extended into the insulating material 118, as shown in FIG. 22B and 22C. As shown in FIG. 22C, in some embodiments, the gate spacers 138 are protected by the mask layer 180 and are not removed during the removal of the portions of the gate electrode layers 172 and gate dielectric layer 170.

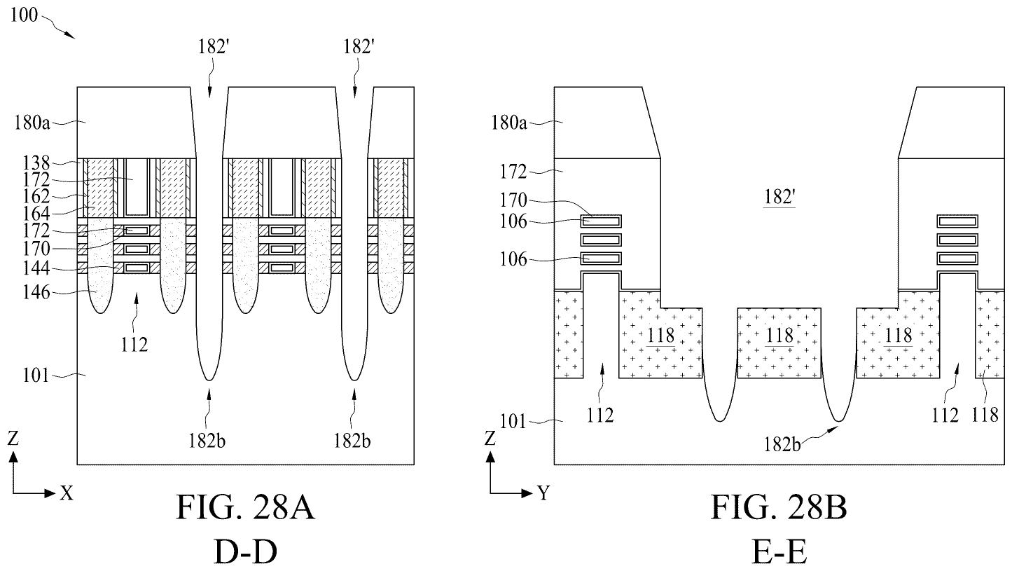

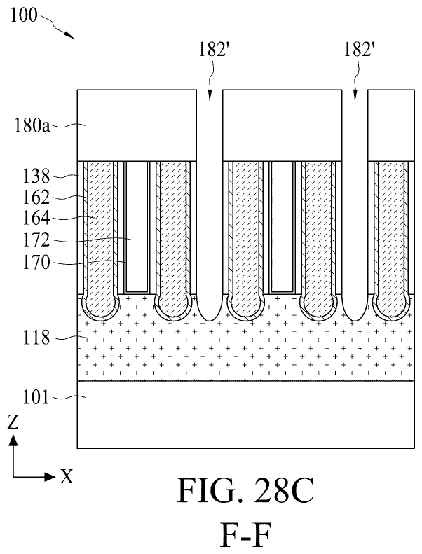

In FIGS. 28A-28C, the exposed gate electrode layers 172, the gate dielectric layers 170, and the fin structures 112 are removed to form openings 182′. The gate dielectric layers 170 may be removed by any suitable etch back process, which may be performed by an anisotropic dry etch, with assistance of wet etch processes. Since there is no protection wall in the line end of CMODE trenches, an anisotropic etch process may avoid the damage to the neighboring metal gate structures. Wet processes may or may not be used to clean the etch by-product or remove the high k dielectrics, such as the gate dielectric layer 170. In some embodiments, a portion of the gate dielectric layer 170 may also be removed by the etch back process.

Thereafter, a fin-cut (or sheet-cut) process is performed to remove the exposed first semiconductor layers 106, the gate dielectric layer 170, the fin structures 112, and a portion of the substrate 101 forming the fin structures 112. The fin-cut process is performed using the patterned mask layer 180a as an etching mask. The fin-cut process may be dry etch, reactive ion etch (RIE), and/or other suitable processes. As a result of the fin-cut process, isolation trenches 182′ are formed and extended into portions of the substrate 101 forming the fin structures 112. The isolation trenches 182′ are to be filled with a dielectric material and form CMODE structures.

In some embodiments, the removal of the exposed first semiconductor layers 106, the gate dielectric layer 170, the fin structures 112, and the portion of the substrate 101 forming the fin structures 112 is achieved using a self-aligned CMODE etch process. The self-aligned CMODE etch process is selected to have high etch selectivity so that the etch rate of the first semiconductor layers 106 is greater than the etch rate of the inner spacers 144. As a result, the inner spacers 144 and therefore the epitaxial source/drain features 146 remain substantially intact after the fin-cut process. The isolation trenches 182′ (and thus subsequent CMODE structures) are formed with a depth sufficient to block leakage current, which may otherwise flow through epitaxial source/drain features, transistors, and silicon substrates.

The high selectivity of the self-aligned CMODE etch process can be achieved using a Cl-based etch chemistry (e.g., Cl₂) and an oxygen-based chemistry (e.g., O₂ or CO₂). To further increase the selectivity of silicon over the hard mask (e.g., SiN), the patterned mask layer 180a may be exposed to a gas mixture comprising C—H based chemistry in the beginning of the self-aligned CMODE etch process to form a polymer protection layer (not shown) on exposed surfaces of the patterned mask layer 180a. The polymer protection layer minimizes the patterned mask layer 180a from being damaged during the fin-cut process. Additionally or alternatively, an oxide-based passivation layer may be formed over the exposed surfaces of the patterned mask layer 180a to facilitate the self-aligned CMODE etch process. In such cases, a break-through etch process using C—H and/or C—F based chemistries may be used to etch the excessive passivation layer in the etch front. Suitable C—H and C—F based chemistries may include, but are not limited to CF₄, CHF₃, CH₂F₂, CHF₃, C₄F₆, or the like. The break-through etch process may also be utilized in the beginning of removing the mask layer 180a and/or by-products are accumulated at the exposed sidewalls of the insulating material 118.

An exemplary self-aligned CMODE etch process may utilize an ICP/resonant antenna plasma source driven by an RF power generator using an AC electrical current operating on a tunable frequency of multiple of 13.56 MHz or 27 MHz. The process chamber may be operated at a pressure in a range of about 1 mTorr to about 200 mTorr and a temperature of about 10 degrees Celsius to about 200 degrees Celsius. The RF power generator is operated to provide source power between about 0 W to about 2500 W. The source power is used to form a plasma from Cl₂, BCl₃, HBr, O₂, and Ar (plasma etching step) and CF₄ and Ar (break-through step). An RF bias power operating in a range of about 0 W to about 2000 W is applied to the pedestal. In some cases, a pulse plasma etch may be used. In such cases, the output of the power generator may be controlled by a pulse signal having a duty cycle in a range of about 5% to 95%. Alternatively, the self-aligned CMODE etch process may use bias power only (with zero source power).

In some alternative embodiments, the fin-cut process is a multi-step process using a first etch scheme and a second etch scheme. The first etch scheme may be a plasma-based etch process employing one or more etchants that selectively remove the first semiconductor layers 106, the metal gate structure, and gate dielectric heterostructures (and portions of the patterned mask layer 180a). The first etch scheme may continue until the isolation trenches 182′ reach a depth at or near the top surface of the insulating material 118. In some cases, the first etch scheme may continue until a sidewall of the insulating material 118 is exposed.

Once the isolation trenches 182′ reach the desired depth needed for the first etch scheme, the second etch scheme is then performed to extend the isolation trenches 182′ into a desired depth below the interface defined by the insulating material 118 and the substrate 101. In some embodiments, the bottom 182b of the isolation trenches 182′ may be at an elevation into an accumulation region of the substrate 101. The term “accumulation region” refers to a non-conductive region in the substrate 101, which is below a depletion region (a conductive region located at/near the well region of the substrate 101). The second etch scheme may be a dry etch process employing one or more etchants that selectively remove the substrate 101 and a portion of the insulating material 118 but do not substantially remove the gate electrode layer 172. The etchant used in the first etch scheme may be a chlorine-based etch chemistry, a bromine-based chemistry, or a chlorine/bromine-based etch chemistry. The etchant used in the second etch scheme may be a fluorine-based etch chemistry, a chlorine-based etch chemistry, a bromine-based etch chemistry, a fluorine/chlorine-based etch chemistry, a fluorine/bromine-based etch chemistry, a chlorine/bromine-based etch chemistry, or any combination thereof. In one exemplary embodiment, the first etch scheme employs a bromine-based etch chemistry and the second etch scheme employs a fluorine-based etch chemistry and a bromine-based etch chemistry, or vice versa. In another exemplary embodiment, the first etch scheme employs a bromine-based etch chemistry and the second etch scheme employs a bromine-based etch chemistry. Exemplary chlorine-based etch chemistry may include, but are not limited to, Cl₂, CHCl₃, CCl₄, BCl₃, or the like, or a combination thereof. Exemplary bromine-based etch chemistry may include, but are not limited to, HBr, Br₂, BBr₃, or the like, or a combination thereof. Exemplary fluorine-containing gas may include, but are not limited to, CF₄, SF₆, CH₂F₂, C₂H₄F₂, CHF₃, C₂F₆, or the like, or a combination thereof.

In some embodiments, after the first etch scheme and prior to the second etch scheme, the semiconductor device structure 100 may be exposed to a gas mixture comprising a silicon-containing precursor (e.g., SiCl₄), a bromine-containing precursor (e.g., HBr), and an inert gas (e.g., Ar), followed by an oxidation process, to form a silicon oxide layer on the exposed surfaces of the sacrificial gate electrode layer 134. The silicon oxide layer helps shrink the critical dimension (CD) of the openings 182 so that the isolation trenches 182′ as formed are extended into the substrate portion of the fin structures 112 in the depletion region with a proper CD. In such cases, an etch process using etch chemistries comprising fluorine-containing gas (e.g., CF₄) and an inert gas (e.g., Ar) may be performed to break through the silicon oxide layer.

In some embodiments, the second etch scheme is a cyclic process including repetitions of a plasma etching step and a break-through step. The plasma etching step may use an inert gas (e.g., Ar), an oxygen-containing gas (e.g., O₂), and any of the etch chemistries (e.g., HBr) mentioned in the second etch scheme above and be configured to remove the substrate portion of the fin structures 112. The break-through step may use an inert gas (e.g., Ar) and/or any of the etch chemistries (e.g., CF₄) mentioned in the second etch scheme above and configured to remove the substrate portion of the fin structures 112, the insulating material 118, the silicon oxide layer (if any), and any debris/by-products formed during the plasma etching step. The cyclic process may be repeated 2 to 5 cycles. In some embodiments, the second etch process further includes an over-etch step following the cyclic process. The over-etch step may use an inert gas (e.g., Ar), an optional oxygen-containing gas (e.g., O₂), and any of the etch chemistries (e.g., HBr) mentioned in the second etch scheme above and be configured to remove additional portion of the substrate 101. An RF bias power may be supplied (to a pedestal upon which the semiconductor device structure 100 is disposed) during the first etch scheme, the plasma etching step of the second etch scheme, and the over-etch step to enable anisotropic etching.

In FIGS. 29A-29C, the isolation trenches 182′ (FIGS. 28A-28C) are filled with a dielectric material 2130. The dielectric material 2130 may be deposit within the isolation trenches 182′ and on the patterned mask layer 180a. In some embodiments, a dielectric liner (not shown) may be disposed between the dielectric material 2130 and the exposed surfaces of the isolation trenches 182′ (FIGS. 28A and 28B). The dielectric material 2130 and the dielectric liner (if any) filled within the isolation trenches 182′ form isolation trench structures 2134a, 2134b (collectively referred to as isolation trench structures 2134). The dielectric material 2130 and the dielectric liner may be made of an oxygen-containing material, such as silicon oxide (SiO₂); a nitrogen-containing material, such as silicon nitride, silicon oxynitride (SiON), SiOCN, SiCN; a low-K dielectric material; or any suitable dielectric material. The dielectric material 2130 may include a material chemically different than the and the dielectric liner, and may be formed by any suitable process, such as a CVD, PECVD, FCVD, or ALD process. In some embodiments, a planarization process, such as a CMP process, may be performed after the isolation trenches 182′ are filled to remove portions of the dielectric material formed over the patterned mask layer 180a. The planarization process is performed until a portion of the patterned mask layer 180a is exposed. The isolation trench structures 2134 extend through the depletion region and into the accumulation region of the substrate 101 to block the leakage current path that may otherwise form through epitaxial source/drain features, transistors, and silicon substrates.

After the isolation trenches 182′ are filled with the dielectric material 2130, a mask structure 152c is formed on the isolation trench structures 2134. In some embodiments, the mask structure 152c is a tri-layer photoresist, such as the mask structure 152. For example, the mask structure 152c may include a bottom layer 154 and a middle layer 156 disposed on the bottom layer 154. The photoresist layer 158 is patterned to have openings 183 formed therein. The openings 183 are arranged so that some openings 183 come across the CMODE structures (e.g., CMODE structures 2134a), while some openings 183 are arranged to not across the CMODE structures (e.g., CMODE structures 2134b). For example, a first plurality of openings 183 may be arranged to come across the CMODE structures 2134a at the wells and the well boundaries, and a second plurality of openings 183 may be arranged to avoid coming across the CMODE structures 2134b at Vcc and Vss. In any case, the openings 183 define the locations where CMG structures are to be formed.

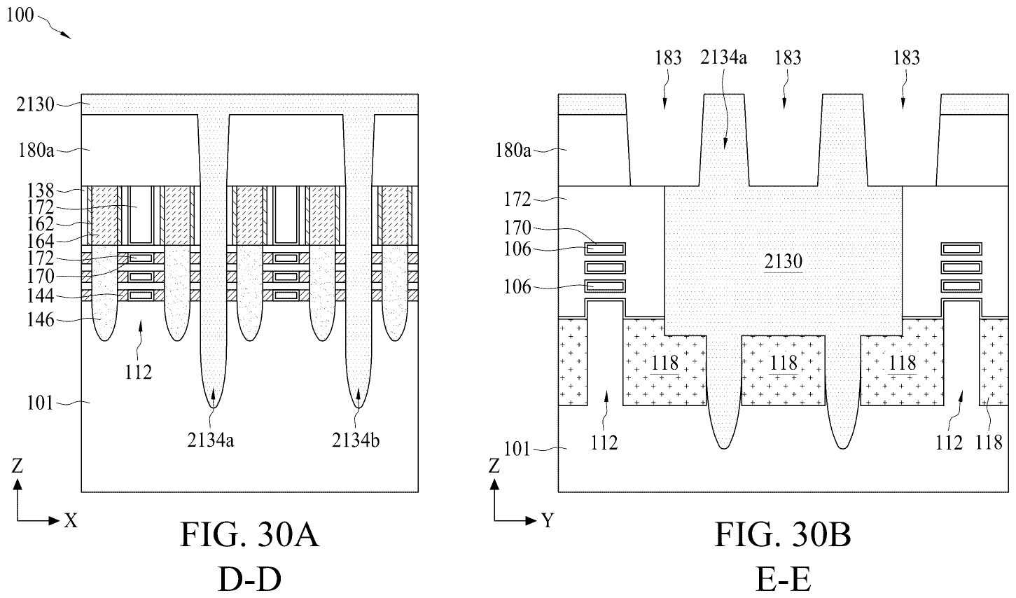

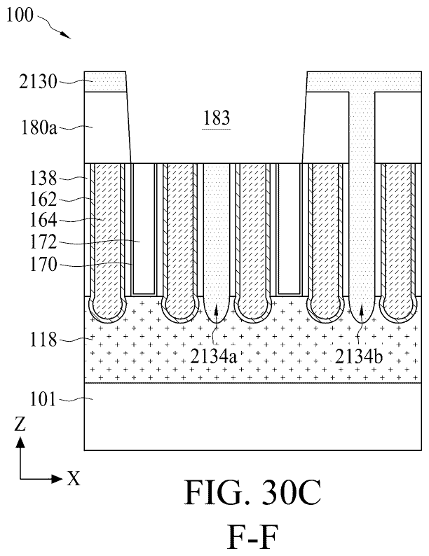

In FIGS. 30A and 30B, one or more etch processes are performed so that the openings 183 are extended into the middle layer 156, the bottom layer 154, the patterned mask layer 180a, and the isolation trench structures 2134. The one or more etch processes may be performed until a portion of the ILD layer 164 is exposed through the openings 183. In some embodiments, a multiple etch process is adapted in which a first etch process is performed to remove portions of the middle layer 156 and the bottom layer 154. The first etch process may continue until a portion of the isolation trench structures 2134 is exposed. Thereafter, the mask structure 152c is removed, and a patterned mask layer (not shown) is formed on the isolation trench structures 2134. The patterned mask layer may have patterns corresponding to the openings 183, which align with the location of the underlying insulating materials 118. A second etch process is then performed to extend the openings 183 through the patterned mask layer 180a and expose the gate electrode layer 172. The second etch process may continue until a portion of the ILD layer 164 is exposed. The first and second etch processes may be a wet etch, a dry etch, or a combination thereof.

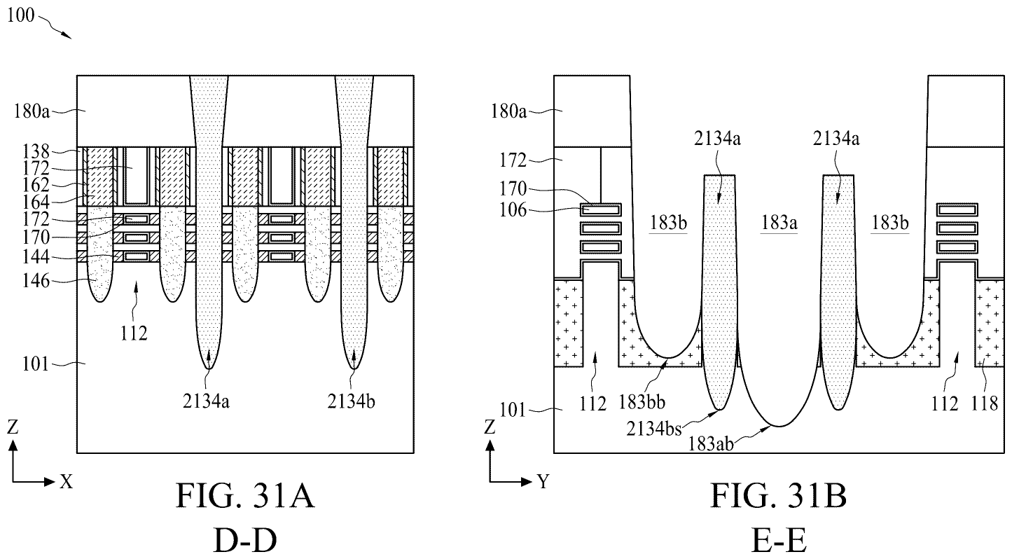

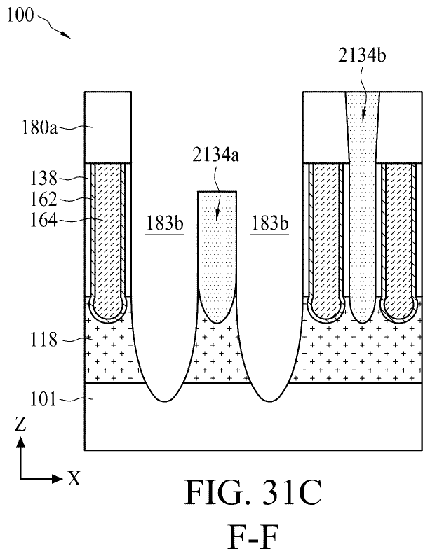

In FIGS. 31A and 31B, the openings 183 are extended vertically through the gate electrode layers 172 and the isolation trench structures 2134, and into the insulating material 118. In some embodiments, the opening 183a between the two adjacent isolation trench structures 2134a may extend into the substrate 101, while the openings 183b between the isolation trench structure 2134a and adjacent fin structure 112 may extend into the insulating material 118. In some cases, the opening 183a may have a bottom 183ab at a first elevation and the openings 183b may have a bottom 183bb at a second elevation higher than the bottom 183ab. The opening 183a is etched to have a greater length than that of the openings 183b due to etch chemistry being used to form CMG isolation trenches may remove oxides (e.g., insulating materials 118) at a faster rate than nitrides (e.g., isolation trench structures 2134). Depending on the application, the isolation trench structure 2134a may have a bottom 2134bs at a third elevation that may be higher or lower than the bottom 183ab of the opening 183a. The openings 183 may be extended by one or more etch processes. For example, a first etch process may use a first etch chemistry (e.g., a chlorine-based chemistry) to selectively remove the isolation trench structures 2134a and the insulating material 118, and a second etch process may use a second etch chemistry (e.g., a fluorine-based chemistry) to selectively remove the gate electrode layers 172 and the insulating material 118. The use of different etch chemistries results in the difference in length of the openings 183a, 183b. The patterned mask layer on the isolation trench structure 2134 protects selected portions of the isolation trench structures 2134, such as isolation trench structures 2134a protruding upwardly between the openings 183a, 183b, to remain substantially intact.

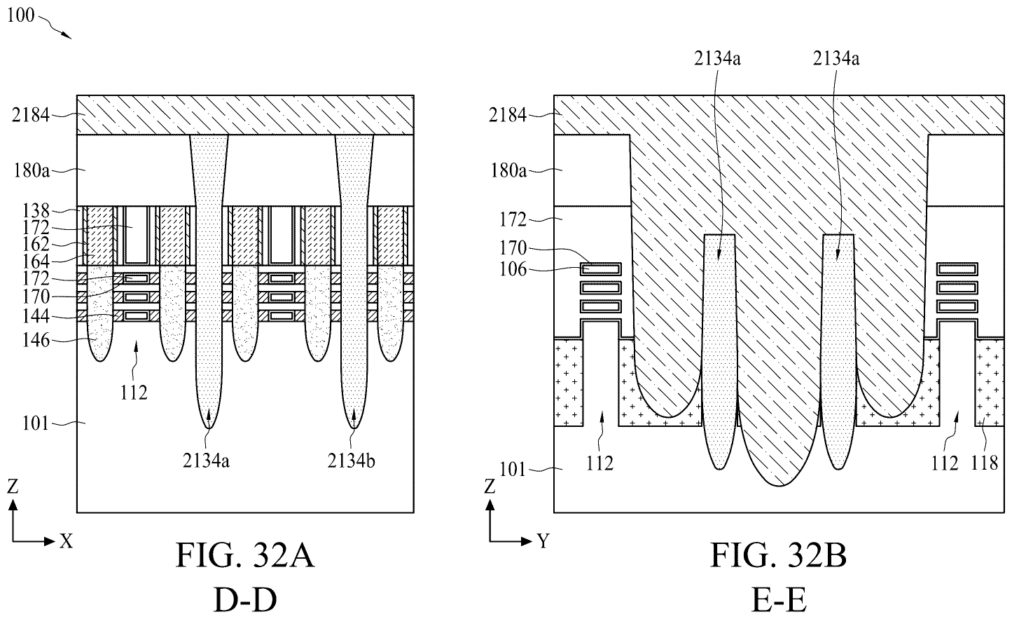

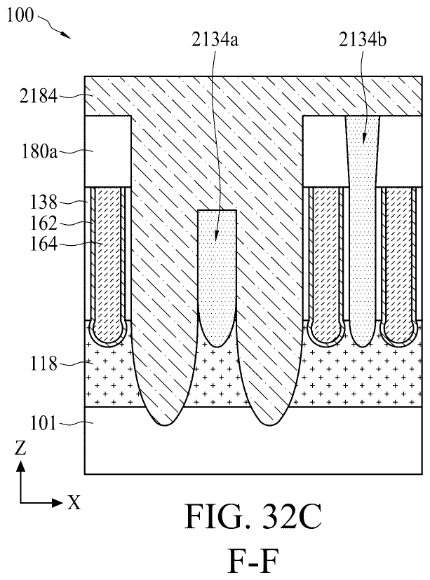

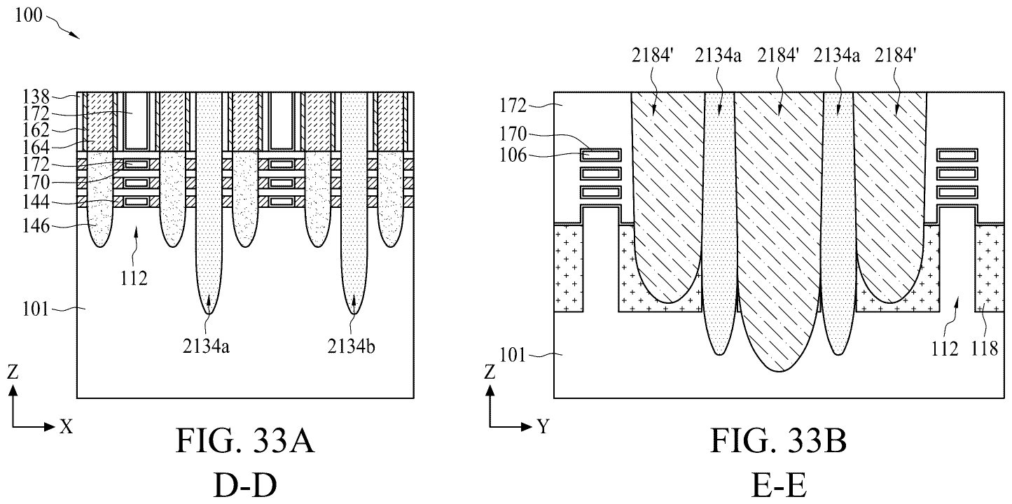

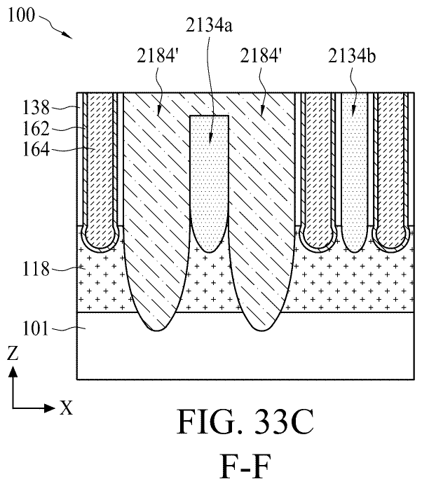

In FIGS. 32A-32C, the openings 183a, 183b are filled with a dielectric material 2184, such as the dielectric material 184 discussed above with respect to FIGS. 16A-16D. The dielectric material 2184 within the openings 183a, 183b forms cut metal gate (CMG) structures 2184′ (FIGS. 33B-33C). The dielectric material 2184 may be formed by any suitable process, such as a CVD, PECVD, FCVD, or ALD process.

In FIGS. 33A-33C, a planarization process, such as a CMP process, may be performed on the semiconductor device structure 100. The CMP process removes excessive portion of the dielectric material 184 and the patterned mask layer 180a. The CMP process may perform until a portion of the ILD layer 164 is exposed.

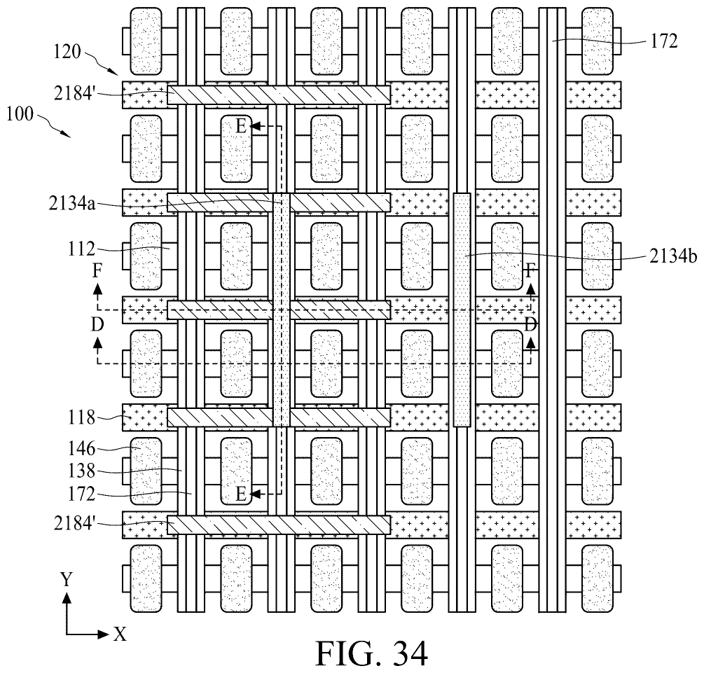

FIG. 34 is a top view of the semiconductor device structure 100 shown in FIGS. 33A-33C, in accordance with some embodiments. Some components of the semiconductor device structure 100, such as the ILD layer 164, the CESL 162, are omitted in FIG. 34 for clarity. Likewise, the CMODE structures 2134a may be intra-well isolations 2406 (FIG. 24) and inter-well isolations 2408 (FIG. 24) disposed within the well regions or at well boundaries of an IC device, respectively, and the CMODE structures 2134b may be pick-up isolations 2410 (FIG. 24) disposed at Vcc and Vss of an IC device.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

Embodiments of the present disclosure provide an improved process to prevent intra-well and inter-well leakages by forming shallower CMODE structures at ground or pick-up wells than CMODE structures at the well boundaries or within the well regions. CMODE structures with different heights (or depths) can be achieved simultaneously by running a Continuous-Metal-On-Diffusion-Edge (CMODE) process at or across regions where a Cut-Metal Gate (CMG) process was performed. The CMODE structures at ground or pick-up wells are made shallower to help lower the well contact resistance, which prevents formation of a parasitic NPN and PNP bipolar junction transistor (BJT) and thus a leakage current path along the parasitic BJTs. As a result, a latch-up in an IC device is avoided and the performance of the device is improved.

A semiconductor device structure is described. The structure includes a substrate, an insulating material disposed on the substrate, a first fin structure extending upwardly from the substrate through the insulating material, a second fin structure extending upwardly from the substrate through the insulating material, wherein the first and second fin structures extend along a first direction. The structure also includes a first isolation trench structure disposed between the first and second fin structures, wherein the first isolation trench structure extends through the insulating material along a second direction perpendicular to the first direction, and the first isolation trench structure includes a first portion extending a first depth into the substrate and a second portion extending a second depth into the substrate, wherein the second depth is different than first depth.

Another embodiment is a semiconductor device structure. The structure includes a substrate, a first fin structure extending upwardly from the substrate, a second fin structure extending upwardly from the substrate, wherein the first and second fin structures are parallelly arranged along a first direction. The structure also includes a first isolation trench structure disposed between the first and second fin structures, wherein the first isolation trench structure extends along a second direction perpendicular to the first direction. The structure also includes a second isolation trench structure disposed between the first and second fin structures, wherein the second isolation trench structure extends along the second direction. The structure further includes a third isolation trench structure disposed between the first and second fin structures, wherein the third isolation trench extends along the first direction to across a portion of the first isolation trench structure, and the third isolation trench structure is separated from the second isolation trench structure by an interlayer dielectric (ILD) layer.

A further embodiment is a method for forming a semiconductor device structure. The method includes forming a plurality of fin structures from a substrate, each fin structure extending along a first direction and comprising a plurality of semiconductor layers vertically stacked. The method also includes forming an insulating material on the substrate, forming a gate electrode layer over the insulating material, wherein the gate electrode layer surrounds a portion of each semiconductor layer. The method also includes removing portions of the gate electrode layer and the insulating material to form a first isolation trench, wherein the first isolation trench extends along the first direction. The method also includes filling the first isolation trench with a first dielectric material to form a first isolation trench structure, removing portions of the gate electrode layer, the semiconductor layers of one or more fin structures of the plurality of fin structures, the first isolation trench structure, the insulating material, and the substrate to form a second isolation trench extending along a second direction perpendicular to the first direction. The method further includes filling the second isolation trench with a second dielectric material to form a second isolation trench structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a substrate;
an insulating material disposed on the substrate;
a first fin structure extending upwardly from the substrate through the insulating material;
a second fin structure extending upwardly from the substrate through the insulating material, the first and second fin structures extending along a first direction;
a first isolation trench structure disposed between the first and second fin structures, the first isolation trench structure extending through the insulating material along a second direction perpendicular to the first direction, the first isolation trench structure comprising:
a first portion extending a first depth into the substrate; and
a second portion extending a second depth into the substrate, wherein the second depth is different than first depth.

2. The semiconductor device structure of claim 1, further comprising:
a second isolation trench structure disposed above the substrate between the first and second fin structures, the second isolation trench extending along the first direction.

3. The semiconductor device structure of claim 2, wherein the first isolation trench structure has a sidewall in contact with the second isolation trench structure.

4. The semiconductor device structure of claim 2, wherein the first isolation trench structure extends through the entire body of the second isolation trench structure from a top surface to a bottom surface.

5. The semiconductor device structure of claim 4, wherein the first isolation trench structure has a first dimension and the second isolation trench structure has a second dimension greater than the first dimension.

6. The semiconductor device structure of claim 2, wherein a portion of the insulating material is disposed between the substrate and a bottom of the second isolation trench structure.

7. The semiconductor device structure of claim 2, wherein each first and second fin structure comprises a plurality of semiconductor layers vertically stacked, and each semiconductor layer being surrounded by a gate electrode layer.

8. The semiconductor device structure of claim 7, wherein the first and second isolation trench structures extend through a portion of the gate electrode layer.

9. The semiconductor device structure of claim 1, wherein each of the first and second portions of the first isolation trench structure has a curved profile.

10. A semiconductor device structure, comprising:
a substrate;
a first fin structure extending upwardly from the substrate;
a second fin structure extending upwardly from the substrate, the first and second fin structures being parallelly arranged along a first direction;
a first isolation trench structure disposed between the first and second fin structures, the first isolation trench structure extending along a second direction perpendicular to the first direction;
a second isolation trench structure disposed between the first and second fin structures, the second isolation trench structure extending along the second direction; and
a third isolation trench structure disposed between the first and second fin structures, the third isolation trench extending along the first direction to across a portion of the first isolation trench structure, and the third isolation trench structure being separated from the second isolation trench structure by an interlayer dielectric (ILD) layer.

11. The semiconductor device structure of claim 10, wherein the first isolation trench structure extends a first depth into the substrate, and the second isolation trench structure extends a second depth into the substrate, and the first depth is greater than the second depth.

12. The semiconductor device structure of claim 11, wherein the first isolation trench structure extends through the entire body of the third isolation trench.

13. The semiconductor device structure of claim 11, wherein the first isolation trench structure comprises:
a first portion having a bottom in the substrate at a first elevation; and
a second portion having a bottom in the substate at a second elevation different than the first elevation.

14. The semiconductor device structure of claim 13, wherein each of the first and second portions of the first isolation trench structure has a curved profile.

15. The semiconductor device structure of claim 10, wherein the first and second isolation trench structure comprise a first dielectric material, and the third isolation trench structure comprises a second dielectric material that is chemically different from the first dielectric material.

16. The semiconductor device structure of claim 10, wherein the first isolation trench structure is located at wells electrically coupled to electrical ground.

17. A method for forming a semiconductor device structure, comprising:
forming a plurality of fin structures from a substrate, each fin structure extending along a first direction and comprising a plurality of semiconductor layers vertically stacked;
forming an insulating material on the substrate;
forming a gate electrode layer over the insulating material, the gate electrode layer surrounding a portion of each semiconductor layer;
removing portions of the gate electrode layer and the insulating material to form a first isolation trench, the first isolation trench extending along the first direction;
filling the first isolation trench with a first dielectric material to form a first isolation trench structure;
removing portions of the gate electrode layer, the semiconductor layers of one or more fin structures of the plurality of fin structures, the first isolation trench structure, the insulating material, and the substrate to form a second isolation trench extending along a second direction perpendicular to the first direction; and
filling the second isolation trench with a second dielectric material to form a second isolation trench structure.

18. The method of claim 17, further comprising:
while forming the second isolation trench, removing portions of the gate electrode layer, the semiconductor layers of one or more fin structures of the plurality of the fin structures, the insulating material, and the substrate to form a third isolation trench extending along the second direction, wherein the third isolation trench is separated from the first isolation trench structure by an interlayer dielectric (ILD) layer; and
filling the third isolation trench with the second dielectric material to form a third isolation trench structure.

19. The method of claim 18, wherein the second isolation trench structure extends a first depth into the substrate, and the third isolation trench structure extends a second depth into the substrate, and the first depth is greater than the second depth.

20. The method of claim 19, wherein the third isolation trench structure is located at wells electrically coupled to electrical ground.
